(19) United States
(12) Patent Application Publication
(10) Pub. No.: US 2025/0176171 A1
(43) Pub. Date: May 29, 2025

(54) MEMORY DEVICE AND FABRICATION METHOD THEREOF

(71) Applicant: Yangtze Memory Technologies Co., Ltd., Wuhan (CN)

(72) Inventors: Yaqin LIU, Wuhan (CN); Wei LIU, Wuhan (CN)

(21) Appl. No.: 18/938,555

(22) Filed: Nov. 6, 2024

(30) Foreign Application Priority Data
Nov. 28, 2023 (CN) 202311614799.9

(51) Int. Cl. H10B 12/00; H01L 23/00; H01L 25/00; H01L 25/065; H01L 25/18; H10B 80/00

(52) U.S. Cl. CPC H10B 12/482; H01L 24/08; H01L 24/80; H01L 25/0657; H01L 25/18; H01L 25/50; H10B 12/05; H10B 12/315; H10B 80/00; H01L 2224/08145; H01L 2224/80895; H01L 2224/80896; H01L 2924/1431; H01L 2924/1436

(57) ABSTRACT

The present disclosure provides a memory device and a fabrication method thereof. The memory device includes a first semiconductor structure including: a semiconductor pillar extending along a first direction with a first end and a second end that are opposite in the first direction; and a bit line located on a side of the semiconductor pillar close to the first end and coupled with the first end. The bit line extends along a second direction perpendicular to the first direction, a first side of the bit line along a third direction and a first side of the semiconductor pillar along the third direction are aligned with each other in the first direction, a size of the bit line in the third direction is less than a size of the semiconductor pillar in the third direction, and the third direction is perpendicular to the first direction and intersects the second direction.

### CROSS-REFERENCE TO RELATED APPLICATIONS

This application claims priority to Chinese Patent Application No. 202311614799.9, filed on Nov. 28, 2023, which is hereby incorporated by reference in its entirety.

### TECHNICAL FIELD

Examples of the present disclosure relate to the field of semiconductor technology, and particularly to a memory device and a fabrication method thereof.

### BACKGROUND

Some memory devices, such as Dynamic Random Access Memory (DRAM), may comprise a memory array and a peripheral circuit. The peripheral circuit may control the memory array and operate the memory array to perform a read, write or refresh operation. In order to improve the performance of memory device, improvement can be made in various aspects of the memory device and its fabrication method.

### SUMMARY

According to some aspects of examples of the present disclosure, a memory device is provided. The memory device comprises a first semiconductor structure, and the first semiconductor structure comprises: a semiconductor pillar extending along a first direction, wherein the semiconductor pillar has a first end and a second end that are opposite in the first direction; and a bit line that is located on a side of the semiconductor pillar close to the first end and is coupled with the first end, wherein the bit line extends along a second direction perpendicular to the first direction, a first side of the bit line along a third direction and a first side of the semiconductor pillar along the third direction are aligned with each other in the first direction, a size of the bit line in the third direction is less than a size of the semiconductor pillar in the third direction, and the third direction is perpendicular to the first direction and intersects the second direction.

In some examples, a second side of the bit line along the third direction is located between the first side and a second side of the semiconductor pillar along the third direction.

In some examples, a projection of the bit line on a first plane is offset from a projection of the semiconductor pillar on the first plane along the third direction, wherein the first plane is perpendicular to the first direction.

In some examples, the memory device further comprises a dielectric layer located between two adjacent ones of the bit lines in the third direction.

In some examples, the dielectric layer comprises: a first dielectric layer, a second dielectric layer, a third dielectric layer, and a fourth dielectric layer disposed sequentially along the third direction, wherein the first dielectric layer is located at an end of the semiconductor pillar close to the first end, a sum of a size of the first dielectric layer and the size of the bit line in the third direction is less than the size of the semiconductor pillar in the third direction, a projection of the first dielectric layer on a second plane overlaps a projection of the bit line on the second plane, and the second plane is perpendicular to the third direction; the second dielectric layer comprises a first portion extending along the first direction and a second portion extending along the third direction, the second portion is located between the first dielectric layer and the first portion, and a projection of the second portion on the second plane overlaps the projection of the bit line on the second plane; and the third dielectric layer and the fourth dielectric layer both extend along the first direction.

In some examples, a composition material of the first dielectric layer and a composition material of the fourth dielectric layer comprise silicon oxide; and a composition material of the second dielectric layer and a composition material of the third dielectric layer both comprise aluminum oxide or silicon nitride.

In some examples, the memory device further comprises: a word line located on at least one side of the semiconductor pillar, wherein at least part of the word line extends along the third direction; and a gate dielectric layer located between the word line and the semiconductor pillar.

In some examples, the word line comprises a first word line and a second word line that are respectively located on two sides of the semiconductor pillar that are opposite along the second direction.

In some examples, at least one of the first word line or the second word line comprises a protrusion located at an end of at least one of the first word line or the second word line close to the bit line; and the protrusion extends in a direction away from the semiconductor pillar.

In some examples, the word line covers one side of the semiconductor pillar along a direction perpendicular to the first direction; or the word line covers two sides of the semiconductor pillar along a direction perpendicular to the first direction; or the word line covers three sides of the semiconductor pillar along a direction perpendicular to the first direction.

In some examples, the memory device further comprises a capacitor structure located on a side of the semiconductor pillar away from the bit line, and the capacitor structure is coupled with the second end.

In some examples, a size of an end of the capacitor structure away from the bit line in at least one of the second direction or the third direction is greater than a size of an end of the capacitor structure close to the bit line in at least one of the second direction or the third direction.

In some examples, the capacitor structure comprises: a first electrode, and a fifth dielectric layer and a second electrode that surround the first electrode, wherein the fifth dielectric layer is located between the first electrode and the second electrode.

In some examples, the memory device further comprises a second semiconductor structure, wherein the second semiconductor structure comprises a peripheral circuit located on a side of the capacitor structure away from the semiconductor pillar, and the second semiconductor structure is bonded with the first semiconductor structure.

In some examples, the second semiconductor structure further comprises a first interconnection layer and a pad that are located on a side surface of the second semiconductor structure away from the first semiconductor structure, wherein the first interconnection layer and the pad are coupled with the second semiconductor structure.

According to some aspects of examples of the present disclosure, a memory device is provided. The memory device comprises: a semiconductor pillar extending along a first direction, wherein the semiconductor pillar has a first end and a second end that are opposite in the first direction; and a bit line that is located on a side of the semiconductor pillar close to the first end and is coupled with the first end, wherein the bit line extends along a second direction perpendicular to the first direction, a first side of the bit line along a third direction and a first side of the semiconductor pillar along the third direction are aligned with each other in the first direction, a size of the bit line in the third direction is less than a size of the semiconductor pillar in the third direction, and the third direction is perpendicular to the first direction and intersects the second direction; a capacitor structure that is located on a side of the semiconductor pillar away from the bit line and is coupled with the second end; and a peripheral circuit located on a side of the capacitor structure away from the semiconductor pillar, wherein the peripheral circuit is at least coupled with the capacitor structure and the bit line.

In some examples, a second side of the bit line along the third direction is located between the first side and a second side of the semiconductor pillar along the third direction.

In some examples, a projection of the bit line on a first plane is offset from a projection of the semiconductor pillar on the first plane along the third direction, wherein the first plane is perpendicular to the first direction.

In some examples, the memory device further comprises a dielectric layer located between two adjacent ones of the bit lines in the third direction.

In some examples, the dielectric layer comprises: a first dielectric layer, a second dielectric layer, a third dielectric layer, and a fourth dielectric layer disposed sequentially along the third direction, wherein the first dielectric layer is located at an end of the semiconductor pillar close to the first end, a sum of a size of the first dielectric layer and the size of the bit line in the third direction is less than the size of the semiconductor pillar in the third direction, a projection of the first dielectric layer on a second plane overlaps a projection of the bit line on the second plane, and the second plane is perpendicular to the third direction; the second dielectric layer comprises a first portion extending along the first direction and a second portion extending along the third direction, the second portion is located between the first dielectric layer and the first portion, and a projection of the second portion on the second plane overlaps the projection of the bit line on the second plane; and the third dielectric layer and the fourth dielectric layer both extend along the first direction.

In some examples, a composition material of the first dielectric layer and a composition material of the fourth dielectric layer comprise silicon oxide; a composition material of the second dielectric layer comprises aluminum oxide or silicon nitride; and a composition material of the third dielectric layer comprises aluminum oxide or silicon nitride.

In some examples, the memory device further comprises: a word line located on at least one side of the semiconductor pillar and extending along the third direction; and a gate dielectric layer located between the word line and the semiconductor pillar.

In some examples, the word line comprises a first word line and a second word line; wherein the first word line and the second word line are respectively located on two sides of one semiconductor pillar that are opposite along the second direction.

In some examples, at least one of the first word line or the second word line comprises a protrusion located at an end of at least one of the first word line or the second word line close to the bit line; and the protrusion extends in a direction away from the semiconductor pillar.

In some examples, the word line covers one side of the semiconductor pillar along a direction perpendicular to the first direction; or the word line covers two sides of the semiconductor pillar along a direction perpendicular to the first direction; or the word line covers three sides of the semiconductor pillar along a direction perpendicular to the first direction.

In some examples, a size of an end of the capacitor structure away from the bit line in at least one of the second direction or the third direction is greater than a size of an end of the capacitor structure close to the bit line in at least one of the second direction or the third direction.

In some examples, the capacitor structure comprises: a first electrode, and a fifth dielectric layer and a second electrode that surround the first electrode, wherein the fifth dielectric layer is located between the first electrode and the second electrode.

In some examples, the semiconductor pillar, the bit line, and the capacitor structure are located in a first semiconductor structure; the peripheral circuit is located in a second semiconductor structure; and the first semiconductor structure is bonded with the second semiconductor structure.

In some examples, the memory device further comprises a first interconnection layer and a pad that are located on a side surface of the second semiconductor structure away from the first semiconductor structure, wherein the first interconnection layer and the pad are coupled with the second semiconductor structure.

According to some aspects of examples of the present disclosure, a first semiconductor structure is formed, and a fabrication method of the first semiconductor structure comprises: forming a semiconductor pillar extending along a first direction, wherein the semiconductor pillar has a first end and a second end that are opposite in the first direction; and forming a bit line extending along a second direction perpendicular to the first direction on a side of the semiconductor pillar close to the first end, wherein the bit line is coupled with the first end, a first side of the bit line along a third direction and a first side of the semiconductor pillar along the third direction are aligned with each other in the first direction, a size of the bit line in the third direction is less than a size of the semiconductor pillar in the third direction, and the third direction is perpendicular to the first direction and intersects the second direction.

In some examples, a method of forming the bit line comprises: providing a first substrate structure, wherein the first substrate structure comprises a first dielectric layer and a semiconductor layer that are stacked together; forming a first trench extending through the semiconductor layer and the first dielectric layer along the first direction, wherein the first trench extends along the second direction, and the first trench divides the semiconductor layer into semiconductor strips; and reducing a size of the first dielectric layer in the third direction, and forming the bit line extending along the second direction on a side of the semiconductor strip close to the first dielectric layer.

In some examples, a fabrication method of the first substrate structure comprises: providing a first substrate comprising a first insulation layer, and providing a second substrate comprising a second insulation layer; and bonding the first insulation layer and the second insulation layer to form the first dielectric layer, and thinning a side surface of the first substrate away from the first dielectric layer to form the semiconductor layer.

In some examples, the method of forming the bit line further comprises: removing part of the first dielectric layer to reduce the size of the first dielectric layer in the third direction, to form a first opening with an opening direction facing the third direction, wherein the first opening extends along the second direction; filling the first opening to form a second dielectric layer, wherein the second dielectric layer covers a sidewall of the first trench, and the second dielectric layer and the first dielectric layer surround a side of the semiconductor strip and surround a side surface of the semiconductor strip close to the first dielectric layer, to expose a side surface of the semiconductor strip away from the first dielectric layer; filling a remaining cavity of the first trench to form a third dielectric layer; removing the second dielectric layer on a side of the first dielectric layer to form a second trench, wherein the second trench exposes the first dielectric layer, the side of the semiconductor strip, and the side surface of the semiconductor strip close to the first dielectric layer; and forming the bit line in a portion of the second trench that extends toward the first dielectric layer.

In some examples, a method of forming the second trench further comprises: removing part of a thickness of the third dielectric layer, to reduce a size of the third dielectric layer in the third direction.

In some examples, the method of forming the bit line comprises: filling the second trench to form a first conductive layer, wherein the first conductive layer comprises a portion extending along the first direction and a portion extending along the third direction respectively, and wherein the portion of the first conductive layer extending along the third direction extends toward the first dielectric layer; and removing the portion of the first conductive layer that extends along the first direction, to form a third trench, wherein the third trench exposes the third dielectric layer and a side of the semiconductor strip, and a remaining portion of the first conductive layer forms the bit line.

In some examples, the fabrication method of the first semiconductor structure further comprises: filling the third trench to form a fourth dielectric layer.

In some examples, a method of forming the semiconductor pillar further comprises: forming a fourth trench extending through the semiconductor strip, wherein the fourth trench divides the semiconductor strip into semiconductor pillars, and the fourth trench extends along the third direction; and the fabrication method of the first semiconductor structure further comprises: forming a gate dielectric layer and a word line sequentially on at least one side of the semiconductor pillar.

In some examples, a method of forming the word line comprises: forming a sixth dielectric layer at bottom of the fourth trench, wherein a size of the sixth dielectric layer in the first direction is less than the size of the semiconductor pillar in the first direction; forming the gate dielectric layer and a second conductive layer sequentially on a sidewall of the fourth trench and on the sixth dielectric layer; and extending through the second conductive layer along the first direction, to form a first word line and a second word line on two sides of the semiconductor pillar that are opposite along the second direction.

In some examples, during extending through the second conductive layer, a portion of the second conductive layer that remains on the sixth dielectric layer forms a protrusion at an end of at least one of the first word line or the second word line close to the bit line, and the protrusion extends in a direction away from the semiconductor pillar.

In some examples, the word line covers one side of the semiconductor pillar along a direction perpendicular to the first direction; or the word line covers two sides of the semiconductor pillar along a direction perpendicular to the first direction; or the word line covers three sides of the semiconductor pillar along a direction perpendicular to the first direction.

In some examples, the fabrication method of the first semiconductor structure further comprises: forming a capacitor structure on a side of the semiconductor pillar away from the bit line, wherein the capacitor structure is coupled with the second end of the semiconductor pillar.

In some examples, a size of an end of the capacitor structure away from the bit line in at least one of the second direction or the third direction is greater than a size of an end of the capacitor structure close to the bit line in at least one of the second direction or the third direction.

In some examples, the capacitor structure comprises: a first electrode, and a fifth dielectric layer and a second electrode that surround the first electrode, wherein the fifth dielectric layer is located between the first electrode and the second electrode.

In some examples, the fabrication method of the memory device comprises: providing a second semiconductor structure; and bonding the second semiconductor structure and the first semiconductor structure on a side of the capacitor structure away from the bit line.

In some examples, the fabrication method further comprises: forming a first interconnection layer and a pad on a side surface of the second semiconductor structure away from the first semiconductor structure, wherein the first interconnection layer and the pad are coupled with the second semiconductor structure.

Examples of the present disclosure provide a memory device. The semiconductor pillar has two ends that are opposite in the first direction; the bit line is located on a side of the semiconductor pillar close to the first end and is coupled with the first end; the bit line extends along the second direction; a first side of the bit line along the third direction and a first side of the semiconductor pillar along the third direction are aligned with each other in the first direction; and a size of the bit line in the third direction is less than a size of the semiconductor pillar in the third direction, so that there is a large spacing between two adjacent ones of the bit lines in the third direction, thereby reducing interference between the bit lines and improving stability of the memory device.

### BRIEF DESCRIPTION OF THE DRAWINGS

FIGS. 1 to 3 are schematic structural diagrams illustrating a memory device according to examples of the present disclosure;

FIGS. 4 and 5 are schematic structural diagrams illustrating a capacitor structure according to examples of the present disclosure;

FIG. 6 is a flow diagram illustrating a fabrication method of a memory device according to examples of the present disclosure;

FIGS. 7 to 29 are schematic diagrams illustrating a fabrication method of a memory device according to examples of the present disclosure; and

FIGS. 30 and 31 are schematic diagrams illustrating an example system according to examples of the present disclosure.

### DETAILED DESCRIPTION

Example implementations disclosed in the present disclosure will be described in more details with reference to drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is obvious to a person skilled in the art that the present disclosure may be implemented without one or more of these details. In other examples, in order to avoid confusing with the present disclosure, some technical features well-known in the art are not described; that is, not all features of actual examples are described herein, and well-known functions and structures are not described in detail.

In the drawings, sizes and relative sizes of layers, areas, and elements may be exaggerated for clarity. Like reference numerals denote like elements throughout.

It is to be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, third, etc. may be used to describe various elements, components, areas, layers, and/or portions, these elements, components, areas, layers, and/or portions should not be limited by those terms. Those terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. When the second element, component, area, layer or portion is discussed, it does not mean that the first element, component, area, layer or portion is necessarily present in the present disclosure.

The spatially relative terms, such as “beneath”, “below”, “lower”, “under”, “over”, “upper”, and the like, may be used herein for ease of description to describe one element or feature's relationship to other elements or features as illustrated in the figures. It should be understood that in addition to orientations shown in the drawings, the spatial relationship terms are intended to further include the different orientations of a device in use and operation. For example, if a device in the figure is turned over, then an element or a feature described as being “below”, “under”, or “beneath” another element or feature will be orientated as being “above” another element or feature. Therefore, the example terms “below” and “beneath” may comprise both upper and lower orientations. The device may be orientated otherwise (rotated by 90 degrees or in other orientations), and the spatially descriptive terms used herein are interpreted accordingly.

The terms used herein are only intended to describe specific examples, and are not used as limitations of the present disclosure. As used herein, unless otherwise indicated expressly in the context, “a”, “an” and “the” in a singular form are also intended to comprise a plural form. It is also to be understood that terms “consist of” and/or “comprise”, when used in this specification, determine the presence of described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

For a more detailed understanding the characteristics and the technical contents of the examples of the present disclosure, implementation of the examples of the present disclosure is set forth in detail below in conjunction with the drawings, and the appended drawings are only used for reference and illustration, instead of being used to limit the examples of the present disclosure.

It is to be understood that, references to “some examples” or “an example” throughout this specification mean that particular features, structures, or characteristics related to the examples or example are included in at least one example of the present disclosure. Therefore, “in some examples” or “in an example” presented throughout this specification does not necessarily refer to the same example. In addition, these specific features, structures or characteristics may be combined in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are used for description only, and do not represent advantages or disadvantages of the examples.

A memory device in the examples of the present disclosure may be a DRAM or at least some devices in a DRAM, and can be applied to a double-data-rate synchronous dynamic random access memory with a DDR4 memory specification or DDR5 memory specification and a low-power double-data-rate synchronous dynamic random access memory with an LPDDR5 memory specification. It is to be noted that the examples of the present disclosure are not limited to the DRAM. However, in the subsequent introduction, only the DRAM is used as an example for clarity of description.

In the DRAM, a memory array may be arranged in rows and columns, so that a memory cell may be addressed by specifying a row and a column of its array. The memory array comprises a plurality of word lines and a plurality of bit lines, and the word lines intersect the bit lines. A memory cell at an intersection of a selected word line and a selected bit line is selected to perform a read, write or refresh operation. The memory cell in the memory array may comprise a capacitor and a transistor, and one memory cell may comprise one transistor and one capacitor. The word line serves as a gate of the transistor. One controlled terminal (source) of the transistor is coupled with one electrode (first electrode) of the capacitor, the other controlled terminal (drain) of the transistor is coupled with the bit line, and the other electrode (second electrode) of the capacitor may be grounded or be applied with other voltages (for example, vdd/2). During a read or write operation, a respective word line may be selected using a word line select signal, and a respective bit line may be selected according to a column select signal. When both the word line and the bit line are selected, the selected memory cell may be located. At this time, the transistor of the selected memory cell is turned on due to an operation voltage applied to the word line, so that a read, write, or refresh operation may be performed on the selected memory cell. In some examples, the capacitor may be replaced with other memory structures, including, but not limited to, a phase change memory structure, a resistive memory structure, or a magnetoresistive memory structure, etc.

In some examples, the capacitor represent logic 1 and 0 through the amount of charges stored therein or the magnitude of voltage difference across two terminals of the capacitor. A voltage signal on the word line is applied to the gate to control on or off of the transistor, thereby achieving selection and unselection of the capacitor, so as to read data information stored in the capacitor through the bit line, or write data to the capacitor through the bit line for storage.

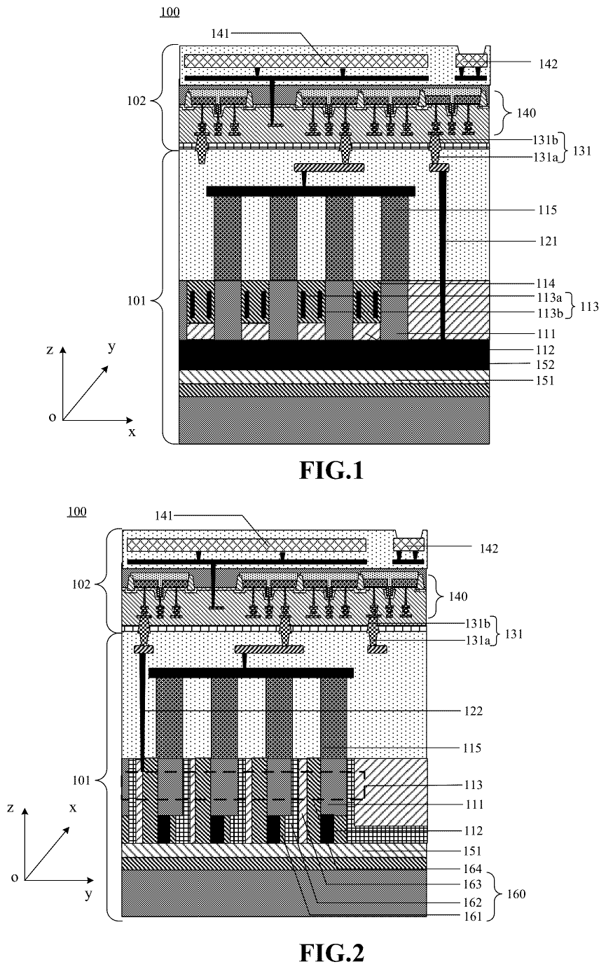

According to some aspects of examples of the present disclosure, with reference to FIG. 1, a memory device 100 is provided. The memory device comprises a first semiconductor structure 101, and the first semiconductor structure 101 comprises: a semiconductor pillar 111 extending along a first direction (z direction), wherein the semiconductor pillar 111 has a first end and a second end that are opposite in the first direction; and a bit line 112 located on a side of the semiconductor pillar 111 close to the first end and coupled with the first end, wherein the bit line 112 extends along a second direction (x direction) perpendicular to the first direction.

With reference to FIG. 2, a first side of the bit line 112 along a third direction (y direction) and a first side of the semiconductor pillar 111 along the third direction are aligned with each other in the first direction, the size of the bit line 112 in the third direction is less than the size of the semiconductor pillar 111 in the third direction, and the third direction is perpendicular to the first direction and intersects the second direction. FIGS. 1 and 2 are schematic cross-sectional views of the memory device 100 in different directions respectively, while some structures of the memory device 100 are illustrated in FIG. 1 and other structures are illustrated in FIG. 2 for ease of explanation.

The first direction in the examples of the present disclosure may be the z direction provided in the drawings, and the z direction may be a thickness direction of the memory device 100. The second direction may be the x direction, and the third direction may be the y direction. The x and y directions are both perpendicular to the z direction. The x and y directions intersect and may be perpendicular to each other or form other included angles. For example, a word line 113 illustrated in FIG. 1 extends along the y direction, the word line 113 may be perpendicular to the bit line 112, or the word line 113 may intersect with the bit line 112 but is not perpendicular to the bit line 112. The examples of the present disclosure do not limit the number and array arrangement of the semiconductor pillars 111, and do not limit the number of bit lines 112 or word lines 113. One bit line 112 may be coupled with first ends of a plurality of semiconductor pillars 111. The first end may be an end in a negative z direction, and the second end may be in a positive z direction. The first end and the second end of the semiconductor pillar 111 may have the same type doping and serve as an active region of the transistor (the source or the drain, which are interchangeable in position). The region between the first end and the second end of the semiconductor pillar 111 may serve as a channel of the transistor. The region between the first end and the second end of the semiconductor pillar 111 may have a different type of doping from that of the first end.

With reference to FIG. 1, a plurality of word lines 113 may be arranged along the x direction. One word line 113 may correspond to a plurality of semiconductor pillars 111 and serve as gates of the plurality of semiconductor pillars 111. The word line 113 is located on a side of the semiconductor pillar 111, and there is a gate dielectric layer 114 between the word line 113 and the side of the semiconductor pillar 111. One semiconductor pillar 111, some word lines 113 corresponding to the semiconductor pillar 111, and the gate dielectric layer 114 may constitute one transistor. An operation voltage may be applied to the word lines 113 to control on and off of the transistor. The word line 113 may cover one side of the semiconductor pillar 111, may cover two sides of the semiconductor pillar 111, or may cover three sides of the semiconductor pillar 111. The word lines 113 illustrated in FIG. 1 cover two sides of the semiconductor pillar 111 in the x direction. One semiconductor pillar 111 corresponds to two word lines 113, and both of the word lines 113 can control the on and off of the transistor, reducing the risk of inaccessibility of some memory cells due to damage of one of the word lines 113. Double word lines 113 can be loaded with a higher operation voltage, thereby improving the stability of the device and increasing a setting margin of operation voltage of the word lines 113. With reference to FIG. 2, a plurality of bit lines 112 may be arranged along the y direction, and each bit line 112 may be coupled with the plurality of semiconductor pillars 111. The word line 113 may be hidden from view by a yoz cross section of the memory device 100, and the word lines 113 shown in the figure are illustrated in a schematic perspective view on the yoz cross section, with the word lines 113 not extending through the semiconductor pillars 111.

Taking one bit line 112 and one semiconductor pillar 111 coupled with it as an example, the first side and the second side of the bit line 112 are two opposite sides of the bit line 112 in the y direction, and the first side and the second side of the semiconductor pillar 111 are two opposite sides of the semiconductor pillar 111 in the y direction. The first side of the bit line 112 may be its left side, and a second side of the bit line 112 may be its right side. The first side of the semiconductor pillar 111 may be its left side, and a second side of the semiconductor pillar 111 may be its right side. The left side of the bit line 112 is aligned with the left side of the semiconductor pillar 111 in the z direction, or is substantially aligned with the left side of the semiconductor pillar within a certain range of process control, for example, the left side of the bit line 112 protrudes from the left side of the semiconductor pillar 111 by a small distance in the negative y direction, or the left side of the semiconductor pillar 111 protrudes from the left side of the bit line 112 by a small distance in the negative y direction. For example, the distance may be less than 5% or less of the size of the bit line 112 in the y direction. The size of the bit line 112 in the y direction is less than the size of the semiconductor pillar 111 in the y direction, and the right side of the bit line 112 is not aligned with the right side of the semiconductor pillar 111, such that there is a large spacing between two adjacent ones of the bit lines 112, thereby reducing interference between the bit lines 112, and improving the stability of the device.

In some examples, the second side of the bit line 112 along the third direction is located between the first side and the second side of the semiconductor pillar 111 along the third direction. As shown in FIG. 2, the right side of the bit line 112 is located between the left side and the right side of the semiconductor pillar 111, and an orthographic projection of the right side of the semiconductor pillar 111 on a first plane perpendicular to the z direction falls between orthographic projections of the left side and the right side of the semiconductor pillar 111 on the first plane.

In some examples, a projection of the bit line 112 on the first plane is offset from a projection of the semiconductor pillar 111 on the first plane along the third direction, wherein the first plane is perpendicular to the first direction. As shown in FIG. 2, an edge of the orthographic projection of the bit line 112 on the first plane does not completely overlap with an edge of the orthographic projection of the semiconductor pillar 111 on the first plane, an orthographic projection of the first side (e.g., the left side) of the bit line 112 on the first plane may overlap with an orthographic projection of the first side (left side) of the semiconductor pillar 111 on the first plane, and an orthographic projection of the second side (e.g., the right side) of the bit line 112 on the first plane may offset from and does not overlap with an orthographic projection of the second side (e.g., the right side) of the semiconductor pillar 111 on the first plane. An orthographic projection of a geometric center of the bit line 112 on the first plane is offset from an orthographic projection of a geometric center of the semiconductor pillar 111 on the first plane, the geometric center of the bit line 112 may be a midline of the bit line 112 in the y direction, and the geometric center of the semiconductor pillar 111 may be a midline of the semiconductor pillar 111 in the y direction.

In some other examples, the first side of the bit line 112 may be its right side, the first side of the semiconductor pillar 111 may be its right side, the right side of the bit line 112 is aligned with the right side of the semiconductor pillar 111 in the z direction, and the left side of the bit line 112 is not aligned with the left side of the semiconductor pillar 111 in the z direction.

In an example, a composition material of the bit line 112 and the word line 113 may include, but is not limited to, a conductive material, such as tungsten, gold, silver, copper, chromium, nickel, titanium, or aluminum, etc. A composition material of the semiconductor pillar 111 may include, but is not limited to, an elemental semiconductor material (e.g., silicon or germanium), a group III-V compound semiconductor material, a group II-VI compound semiconductor material, an organic semiconductor material or other semiconductor materials known in the art.

In some examples, with reference to FIG. 2, the memory device 100 further comprises a dielectric layer 160 located between two adjacent ones of the bit lines 112 in the third direction. The dielectric layer 160 may comprise a single film layer structure or may comprise a plurality of film layer structures. At least part of the dielectric layer 160 is disposed between two adjacent ones of the bit lines 112, and the dielectric layer 160 may have an L shape as shown in FIG. 2, with a portion located between two adjacent ones of the semiconductor pillars 111 and the other portion located between two adjacent ones of the bit lines 112. The dielectric layer 160 is used to electrically isolate the adjacent ones of the bit lines 112, to electrically isolate the adjacent ones of the semiconductor pillars 111, and to support the device structure. In some other examples, the dielectric layer 160 comprises a plurality of film layer structures formed sequentially. The plurality of film layer structures have the same or similar composition materials, there may be no obvious physical boundary between the film layer structures, and the plurality of film layer structures may exhibit an integral film layer structure morphology.

In some examples, with reference to FIG. 2, the dielectric layer 160 comprises: a first dielectric layer 161, a second dielectric layer 162, a third dielectric layer 163, and a fourth dielectric layer 164 disposed sequentially along the third direction. The first dielectric layer 161 is located at an end of the semiconductor pillar 111 close to the first end, a sum of the size of the first dielectric layer 161 and the size of the bit line 112 in the third direction is less than the size of the semiconductor pillar 111 in the third direction, a projection of the first dielectric layer 161 on a second plane overlaps a projection of the bit line 112 on the second plane, and the second plane is perpendicular to the third direction. The second dielectric layer 162 comprises a first portion extending along the first direction and a second portion extending along the third direction, the second portion is located between the first dielectric layer 161 and the first portion, and a projection of the second portion on the second plane overlaps the projection of the bit line 112 on the second plane. Both the third dielectric layer 163 and the fourth dielectric layer 164 extend along the first direction.

In FIG. 2, the dielectric layer 160 may comprise a plurality of film layer structures disposed sequentially along the y direction. The first dielectric layer 161 is relatively close to the first end of the semiconductor pillar 111 and may be located below the semiconductor pillar 111 in the figure. The first dielectric layer 161 extends in the y direction, and two sides of the first dielectric layer 161 are between the left and right sides of the semiconductor pillar 111. An orthographic projection of the first dielectric layer 161 on the second plane perpendicular to the y direction falls within or overlaps an orthographic projection of the bit line 112 on the second plane, and an orthographic projection of the first dielectric layer 161 on the first plane perpendicular to the z direction overlaps the orthographic projection of the semiconductor pillar 111 on the first plane. The second dielectric layer 162 may have an L shape, with the first portion of the second dielectric layer 162 extending along the z direction and the second portion extending toward the first dielectric layer 161 along the y direction. The second portion is located between the first portion and the first dielectric layer 161. An orthographic projection of the second portion on the second plane falls within or overlaps the orthographic projection of the bit line 112 on the second plane, and an orthographic projection of the second portion on the first plane overlaps the orthographic projection of the semiconductor pillar 111 on the first plane. The second dielectric layer 162 covers part of the first end (the bottom of the semiconductor pillar 111 in FIG. 2) of the semiconductor pillar 111, and the right side of the semiconductor pillar 111. The third dielectric layer 163 is located between the second portion of the second dielectric layer 162 and the fourth dielectric layer 164. The first portion and the second portion of the second dielectric layer 162 are only for the purpose of illustration, and there is no obvious physical boundary therebetween.

In some examples, a composition material of the first dielectric layer 161 and the fourth dielectric layer 164 comprises silicon oxide; and a composition material of the second dielectric layer 162 and the third dielectric layer 163 comprises aluminum oxide or silicon nitride. In a semiconductor fabrication process, some processes have high selectivity parameters for the film layer structures. For example, in an etching process, the first dielectric layer 161, the second dielectric layer 162, the third dielectric layer 163, and the fourth dielectric layer 164 may be selected from different combinations of materials to satisfy different selectivities of different etchants, and different film layer materials may be also conducive to reducing stress concentration, thereby improving the stability of the device structure. In an example, the composition materials of the first dielectric layer 161 and the fourth dielectric layer 164 may be the same, and may comprise silicon oxide. The second dielectric layer 162 and the third dielectric layer 163 may both comprise aluminum oxide or both comprise silicon nitride. Alternatively, the second dielectric layer 162 and the third dielectric layer 163 may have different materials, for example, the second dielectric layer 162 may comprise aluminum oxide and the third dielectric layer 163 may comprise silicon nitride; and for another example, the second dielectric layer 162 may comprise silicon nitride and the third dielectric layer 163 may comprise aluminum oxide.

In some examples, with reference to FIG. 1, the memory device 100 further comprises: a word line 113 located on at least one side of the semiconductor pillar 111, wherein at least part of the word line 113 extends along the third direction; and a gate dielectric layer 114 located between the word line 113 and the semiconductor pillar 111. In some examples, the word line 113 comprises a first word line 113a and a second word line 113b, wherein the first word line 113a and the second word line 113b are respectively located on two sides of the semiconductor pillar 111 that are opposite along the second direction.

The first word line 113a and the second word line 113b illustrated in FIG. 1 cover the two sides of the semiconductor pillar 111 in the x direction respectively. One semiconductor pillar 111 corresponds to two word lines 113. There is the gate dielectric layer 114 between the first word line 113a and one side of the semiconductor pillar 111, and there is the gate dielectric layer 114 between the second word line 113b and the other side of the semiconductor pillar 111 that are opposite along the x direction. The first word line 113a may be a word line on the right side of the semiconductor pillar 111, and the second word line 113b may be a word line on the left side of the semiconductor pillar 111. Both of the word lines can control the on and off of the transistor, reducing the risk of inaccessibility of some memory cells due to damage of one of the word lines. Double word lines can be loaded with a higher operation voltage, thereby improving the stability of the device and increasing the setting margin of operation voltage of the word lines. In some other examples, one semiconductor pillar 111 may correspond to one word line 113, and the word line 113 is disposed on one side of the semiconductor pillar 111. In an example, a composition material of the gate dielectric layer 114 may include, but is not limited to, an insulation material, such as silicon oxide, silicon oxynitride, or aluminum oxide, etc.

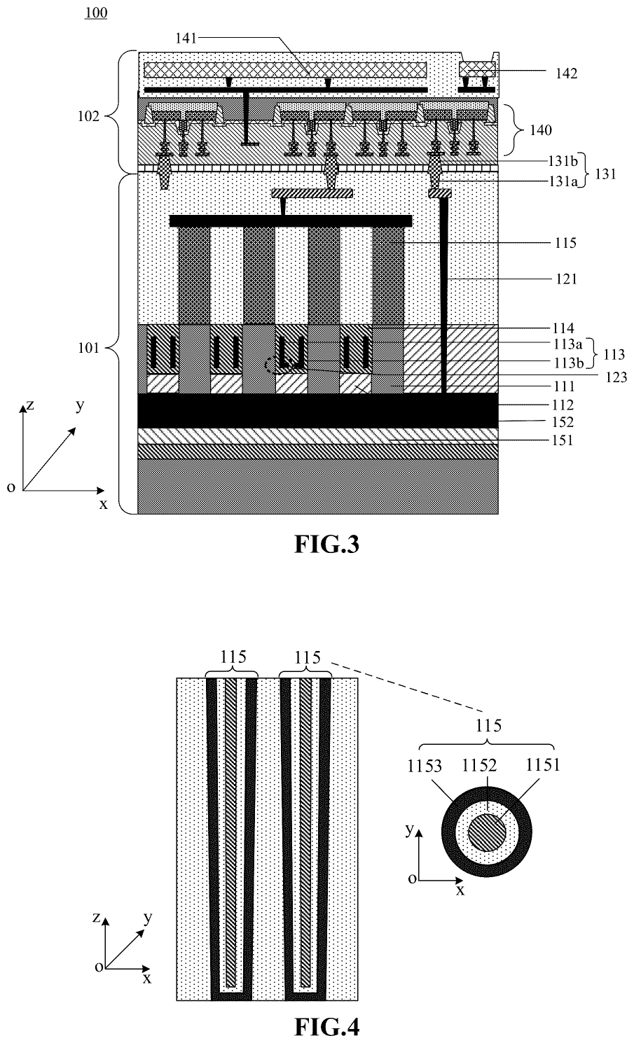

In some examples, with reference to FIG. 3, at least one of the first word line 113a or the second word line 113b comprises a protrusion 123 located at an end of at least one of the first word line 113a or the second word line 113b close to the bit line 112; and the protrusion 123 extends in a direction away from the semiconductor pillar 111. Taking two adjacent semiconductor pillars 111 as an example, the protrusion 123 at the bottom of the first word line 113a on the right side of one semiconductor pillar 111 extends away from the semiconductor pillar 111 in a positive x direction, and the protrusion 123 at the bottom of the second word line 113b on the left side of the other semiconductor pillar 111 extends away from the semiconductor pillar 111 in a negative x direction, and the two protrusions 123 do not contact each other. It is to be noted that the protrusion 123 may be located on a side of any semiconductor pillar 111. The protrusions 123 do not contact each other, and the first word line 113a and the second word line 113b are still electrically isolated from each other. Compared with a solution without any protrusions 123, the examples of the present disclosure can reduce the difficulty of fabricating the word lines 113, which is conducive to enlarging a fabrication process window for the word lines 113, e.g., enlarging an etching process window.

In some examples, the word line 113 covers one side of the semiconductor pillar 111 along a direction perpendicular to the first direction; or the word line 113 covers two sides of the semiconductor pillar 111 along a direction perpendicular to the first direction; or the word line 113 covers three sides of the semiconductor pillar 111 along a direction perpendicular to the first direction. With reference to FIG. 2, one side of the semiconductor pillar 111 in the y direction is covered by the dielectric layer 160, and the word line 113 may cover any one of the other three sides of the semiconductor pillar 111 that are not covered by the dielectric layer 160. The semiconductor pillar 111 may correspond to either one of the first word line 113a and the second word line 113b. The word line 113 extends along the y direction and covers, along the x direction, one side of the semiconductor pillar 111 in the x direction. Alternatively, one semiconductor pillar 111 corresponds to two word lines 113, i.e., the first word line 113a and the second word line 113b, which cover two sides of the semiconductor pillar 111 along the x direction. Alternatively, a bridging structure 1132 is disposed between the first word line 113a and the second word line 113b corresponding to one semiconductor pillar 111. The bridging structure 1132 extends along the x direction and covers one of opposite sides of the dielectric layer 160 along the y direction. The bridging structure 1132 may be part of the word line 113, and is shown in FIG. 26 below.

In some examples, with reference to FIGS. 1 and 2, the memory device 100 further comprises a capacitor structure 115 located on a side of the semiconductor pillar 111 away from the bit line 112, and the capacitor structure 115 is coupled with the second end.

In some examples, a size of an end of the capacitor structure 115 away from the bit line 112 in at least one of the second direction or the third direction is greater than a size of an end of the capacitor structure 115 close to the bit line 112 in at least one of the second direction or the third direction.

In some examples, the capacitor structure 115 comprises: a first electrode 1151, and a fifth dielectric layer 1152 and a second electrode 1153 that surround the first electrode 1151. The fifth dielectric layer 1152 is located between the first electrode 1151 and the second electrode 1153.

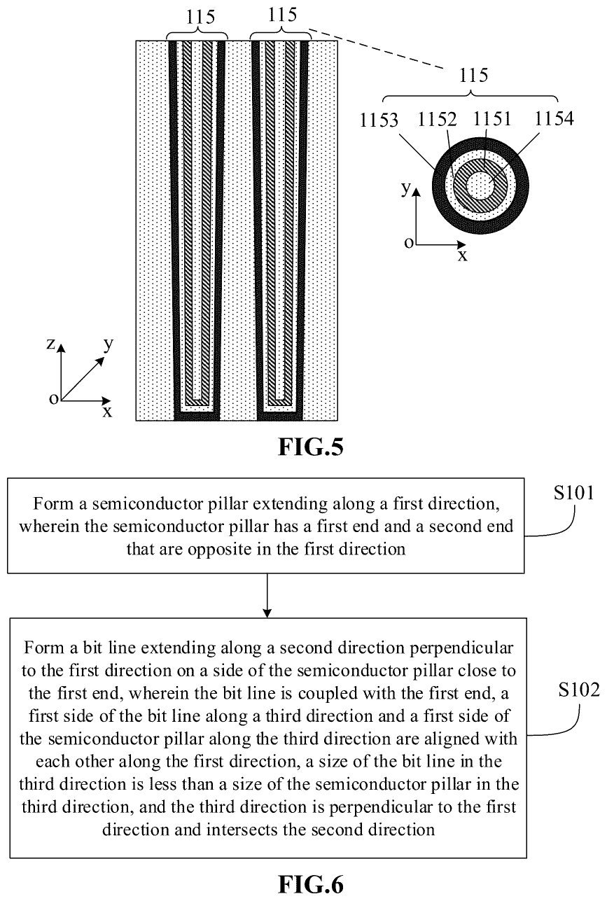

FIGS. 4 and 5 illustrate a cross-sectional view of an example capacitor structure 115 on an xoz plane, and also illustrate a cross-sectional view of the capacitor structure 115 on an xoy plane. With reference to FIGS. 4 and 5, the capacitor structure 115 may comprise a pillar structure. The size of the end of the capacitor structure 115 away from the bit line 112 in at least one of the x direction or the y direction is equal to the size of the end of the capacitor structure 115 close to the bit line 112, or greater than the size of the end of the capacitor structure 115 close to the bit line 112. In FIG. 4, along the x direction, the capacitor structure 115 comprises: a first electrode 1151, and a fifth dielectric layer 1152 and a second electrode 1153 that surround the first electrode 1151. The fifth dielectric layer 1152 is located between the first electrode 1151 and the second electrode 1153. The first electrode 1151 may have a pillar structure, and the fifth dielectric layer 1152 and the second electrode 1153 are film layer structures surrounding the first electrode 1151. In FIG. 5, along the x direction, the capacitor structure 115 may further comprise: a core portion 1154, wherein the first electrode 1151, the fifth dielectric layer 1152, and the second electrode 1153 are disposed around the core portion 1154. The core portion 1154 may have a pillar structure, and the first electrode 1151, the fifth dielectric layer 1152 and the second electrode 1153 are all film layer structures. The second electrode 1153 of the capacitor structure 115 may be coupled with the end of the corresponding semiconductor pillar 111 away from the bit line 112, and first electrodes 1151 of a plurality of capacitor structures 115 may be coupled with an interconnection structure, to achieve grounding or access to other operation voltages.

In an example, a composition material of the first electrode 1151 and the second electrode 1153 may include, but is not limited to, a conductive material, such as tungsten, gold, silver, platinum, copper, aluminum, titanium or nickel, etc. A composition material of the fifth dielectric layer 1152 and the core portion 1154 may include, but is not limited to, an insulation material, such as silicon oxide, silicon nitride, silicon oxynitride, or aluminum oxide, etc.

In some examples, with reference to FIGS. 1 and 2, the memory device 100 further comprises a second semiconductor structure 102. The second semiconductor structure 102 comprises a peripheral circuit 140 located on a side of the capacitor structure 115 away from the semiconductor pillar 111, and the second semiconductor structure 102 is bonded with the first semiconductor structure 101. The capacitor structure 115 is located between the peripheral circuit 140 and the semiconductor pillar 111, and the semiconductor pillar 111 is located between the bit line 112 and the capacitor structure 115.

Devices such as the semiconductor pillar 111, the bit line 112, the word line 113, and the capacitor structure 115, etc. are located in the first semiconductor structure 101, and the peripheral circuit 140 is located in the second semiconductor structure 102. The second semiconductor structure 102 may comprise various devices, including a CMOS structure, to construct the peripheral circuit 140. A method of bonding the first semiconductor structure 101 and the second semiconductor structure 102 may include hybrid bonding.

Before the bonding is completed, planes to be bonded of the first semiconductor structure 101 and the second semiconductor structure 102 have a bonding contact 131a and a bonding contact 131b respectively, for leading out electrical signals of the semiconductor structures to the bonded planes respectively. The bonding contact 131 may include a conductive structure, such as a pad or a conductive plug, etc. The planes to be bonded of the first semiconductor structure 101 and the second semiconductor structure 102 are bonded, and an interface where the planes to be bonded of the two semiconductor structures contact each other is a bonding interface. The bonding contact 131a and the bonding contact 131b of the first semiconductor structure 101 and the second semiconductor structure 102 contact each other at the bonding interface, to achieve electrical signal interconnection between the first semiconductor structure 101 and the second semiconductor structure 102. There may be no physical boundary between the bonding contact 131a and the bonding contact 131b after the bonding, and the bonding contact 131a and the bonding contact 131b may be considered as the bonding contact 131 extending through the bonding interface.

In some examples, the memory device 100 further comprises a first contact structure 121 coupled with the bit line 112 as shown in FIG. 1. The first contact structure 121 leads out an electrical signal of the bit line 112 to the bonding interface and is coupled with the bonding contact 131, so as to achieve electrical signal interconnection with the second semiconductor structure 102 through the bonding contact 131, such as electrical signal interconnection with the peripheral circuit 140. The memory device 100 further comprises a second contact structure 122 coupled with the word line 113 as shown in FIG. 2. The second contact structure 122 leads out an electrical signal of the word line 113 and achieves electrical signal interconnection with the second semiconductor structure 102.

In some other examples, the second semiconductor structure 102 and the first semiconductor structure 101 may be not connected by bonding. The second semiconductor structure 102 is formed based on the structure of the first semiconductor structure 101, the bonding contact 131 serves as a conductive contact or no bonding contact 131 is provided, and the first contact structure 121 and the second contact structure 122 are coupled with an interconnection structure in the peripheral circuit 140 to complete the electrical signal interconnection.

In an example, the peripheral circuit 140 may include, but is not limited to, a sense amplifier, a row decoder, a column decoder, a voltage generator, etc. The sense amplifier is coupled with the bit line 112. The sense amplifier may be configured to capture a weak voltage fluctuation on the bit line 112, and recover a capacitor voltage of the memory cell locally according to the voltage fluctuation. The sense amplifier may comprise a latch, which may latch the value of the recovered capacitor voltage, such that information stored in the memory cell is transferred from the capacitor to the sense amplifier. The sense amplifier may comprise a differential sense amplifier coupled with two bit lines 112, which operates with one selected bit line and a complementary bit line that serves as a reference line, to detect and amplify voltage difference on a pair of bit lines. The row decoder is configured to perform row addressing on the memory array and apply an operation voltage to the word line 113. The column decoder is configured to perform column addressing on the memory array and apply a voltage to the bit line 112 or receive a voltage from the bit line 112. The voltage generator generates high and low voltages required by each device.

In some examples, with reference to FIGS. 1 and 2, the second semiconductor structure 102 further comprises a first interconnection layer 141 and a pad 142 that are located on a side surface of the second semiconductor structure 102 away from the first semiconductor structure 101, and the first interconnection layer 141 and the pad 142 are coupled with the second semiconductor structure 102. The first interconnection layer 141 may be coupled with a device in the peripheral circuit 140, to provide power or communication for the device in the peripheral circuit 140. The pad 142 may serve as an IO interface of the memory device 100 for external power supply or external communication of the memory device 100.

In an example, a composition material of the first contact structure 121, the second contact structure 122, the bonding contact 131, and the pad 142 may include, but is not limited to, a conductive material, such as tungsten, gold, silver, platinum, copper, aluminum, titanium or nickel, etc.

According to some aspects of examples of the present disclosure, a memory device 100 is provided. The memory device 100 comprises: with reference to FIG. 1, a semiconductor pillar 111 extending along a first direction (z direction), wherein the semiconductor pillar 111 has a first end and a second end that are opposite in the first direction; and a bit line 112 located on a side of the semiconductor pillar 111 close to the first end and coupled with the first end, wherein the bit line 112 extends along a second direction (x direction) perpendicular to the first direction, with reference to FIG. 2, a first side of the bit line 112 along a third direction (y direction) and a first side of the semiconductor pillar 111 along the third direction are aligned with each other in the first direction, the size of the bit line 112 in the third direction is less than the size of the semiconductor pillar 111 in the third direction, and the third direction is perpendicular to the first direction and intersects the second direction; a capacitor structure 115 located on a side of the semiconductor pillar 111 away from the bit line 112 and coupled with the second end; and a peripheral circuit 140 located on a side of the capacitor structure 115 away from the semiconductor pillar 111, wherein the peripheral circuit 140 is at least coupled with the capacitor structure 115 and the bit line 112. The capacitor structure 115 is located between the peripheral circuit 140 and the semiconductor pillar 111, and the semiconductor pillar 111 is located between the bit line 112 and the capacitor structure 115.

In some examples, the memory device 100 further comprises a word line 113 extending in the y direction. Devices such as the semiconductor pillar 111, the capacitor structure 115, the bit line 112, the word line 113, and the peripheral circuit 140, etc. may be located in the same semiconductor structure. In some other examples, the semiconductor pillar 111, the capacitor structure 115, the bit line 112, and the word line 113 may be located in one semiconductor structure, and the peripheral circuit 140 may be disposed in another semiconductor structure, and electrical signal interconnection between the two semiconductor structures may be achieved by bonding.

In some examples, the second side of the bit line 112 along the third direction is located between the first side and the second side of the semiconductor pillar 111 along the third direction.

In some examples, a projection of the bit line 112 on the first plane is offset from a projection of the semiconductor pillar 111 on the first plane along the third direction, wherein the first plane is perpendicular to the first direction.

In some examples, the memory device 100 further comprises a dielectric layer located between two adjacent ones of the bit lines 112 in the third direction.

In some examples, the dielectric layer comprises: a first dielectric layer 161, a second dielectric layer 162, a third dielectric layer 163, and a fourth dielectric layer 164 disposed sequentially along the third direction, wherein the first dielectric layer 161 is located at an end of the semiconductor pillar 111 close to the first end, a sum of the size of the first dielectric layer 161 and the size of the bit line 112 in the third direction is less than the size of the semiconductor pillar 111 in the third direction, a projection of the first dielectric layer 161 on a second plane overlaps a projection of the bit line 112 on the second plane, and the second plane is perpendicular to the third direction; the second dielectric layer 162 comprises a first portion extending along the first direction and a second portion extending along the third direction, the second portion is located between the first dielectric layer 161 and the first portion, and a projection of the second portion on the second plane overlaps the projection of the bit line 112 on the second plane; and both the third dielectric layer 163 and the fourth dielectric layer 164 extend along the first direction.

In some examples, a composition material of the first dielectric layer 161 and the fourth dielectric layer 164 comprises silicon oxide; a composition material of the second dielectric layer 162 comprises aluminum oxide or silicon nitride; and a composition material of the third dielectric layer 163 comprises aluminum oxide or silicon nitride.

In some examples, the memory device 100 further comprises: a word line 113 located on at least one side of the semiconductor pillar 111, wherein at least part of the word line 113 extends along the third direction; and a gate dielectric layer 114 located between the word line 113 and the semiconductor pillar 111.

In some examples, the word line 113 comprises a first word line 113a and a second word line 113b; and the first word line 113a and the second word line 113b are respectively located on two sides of one semiconductor pillar 111 that are opposite along the second direction.

In some examples, at least one of the first word line 113a or the second word line 113b comprises a protrusion 123 located at an end of at least one of the first word line 113a or the second word line 113b close to the bit line 112; and the protrusion 123 extends in a direction away from the semiconductor pillar 111.

In some examples, the word line 113 covers one side of the semiconductor pillar 111 along a direction perpendicular to the first direction; or the word line 113 covers two sides of the semiconductor pillar 111 along a direction perpendicular to the first direction; or the word line 113 covers three sides of the semiconductor pillar 111 along a direction perpendicular to the first direction.

In some examples, a size of an end of the capacitor structure 115 away from the bit line 112 in at least one of the second direction or the third direction is greater than a size of an end of the capacitor structure 115 close to the bit line 112 in at least one of the second direction or the third direction.

In some examples, the capacitor structure 115 comprises: a first electrode 1151, and a fifth dielectric layer 1152 and a second electrode 1153 that surround the first electrode 1151, wherein the fifth dielectric layer 1152 is located between the first electrode 1151 and the second electrode 1153.

In some examples, the semiconductor pillar 111, the bit line 112, and the capacitor structure 115 are located in a first semiconductor structure 101; the peripheral circuit 140 is located in a second semiconductor structure 102; and the first semiconductor structure 101 is bonded with the second semiconductor structure 102.

In some examples, the memory device 100 further comprises a first interconnection layer 141 and a pad 142 that are located on a side surface of the second semiconductor structure 102 away from the first semiconductor structure 101, wherein the first interconnection layer 141 and the pad 142 are coupled with the second semiconductor structure 102.

According to some aspects of examples of the present disclosure, FIG. 6 provides a flow diagram of a fabrication method of a memory device 100, which comprises forming the first semiconductor structure 101. With reference to FIG. 6, a fabrication method of the first semiconductor structure 101 comprises:

forming a semiconductor pillar extending along a first direction, wherein the semiconductor pillar has a first end and a second end that are opposite in the first direction; and

forming a bit line extending along a second direction perpendicular to the first direction on a side of the semiconductor pillar close to the first end, wherein the bit line is coupled with the first end; a first side of the bit line along a third direction and a first side of the semiconductor pillar along the third direction are aligned with each other in the first direction; and a size of the bit line in the third direction is less than a size of the semiconductor pillar in the third direction, wherein the third direction is perpendicular to the first direction and intersects the second direction. In some examples, the fabrication method may comprise: providing a first substrate structure 13, wherein the first semiconductor structure 101 is formed in the first substrate structure 13.

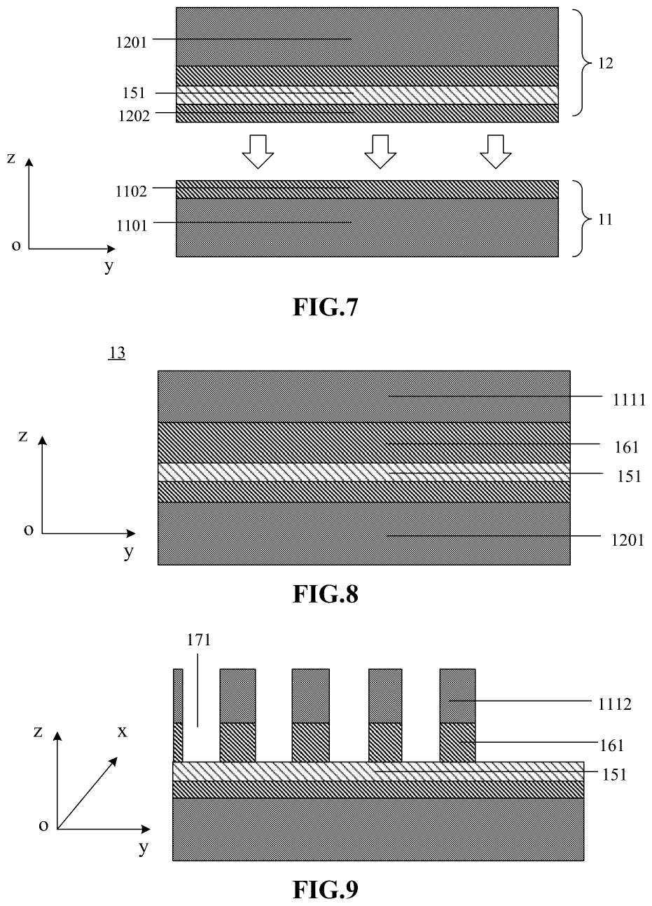

In some examples, a fabrication method of the first substrate structure 13 comprises: with reference to FIG. 7, providing a first substrate 11 comprising a first insulation layer 1102, and providing a second substrate 12 comprising a second insulation layer 1202; bonding the first insulation layer 1102 and the second insulation layer 1202 to form the first dielectric layer 161; and thinning a side surface of the first substrate 11 away from the first dielectric layer 161 to form the semiconductor layer 1111, thereby obtaining the first substrate structure 13 as shown in FIG. 8. The first insulation layer 1102 and the second insulation layer 1202 may comprise silicon oxide, and the first insulation layer 1102 and the second insulation layer 1202 may be bonded through a thermal compression bonding process, after which there may be no obvious physical boundary therebetween. The first insulation layer 1102 may be formed on a first substrate 1101 by deposition, and the first insulation layer 1102 may be an oxide layer formed by oxidation in a furnace or by natural oxidation in air. The second insulation layer 1202 may be formed on a second substrate 1201 by deposition, and there may be other film layers, such as a stop layer 151, between the second insulation layer 1202 and the second substrate 1201. The first substrate 1101 and the second substrate 1201 may be a semiconductor wafer or part of a diced semiconductor wafer. A surface of the first substrate 1101 away from the first dielectric layer 161 is thinned, and the first substrate 1101 remained after the thinning serves as the semiconductor layer 1111. The thinning process may include chemical-mechanical polishing, wheel grinding, or a combination thereof.

A composition material of the first substrate 1101 and the second substrate 1201 may include, but is not limited to, an elemental semiconductor material (e.g., silicon or germanium), a group III-V compound semiconductor material, a group II-VI compound semiconductor material, an organic semiconductor material or other semiconductor materials known in the art. In some other examples, the first substrate structure 13 shown in FIG. 8 may be a Silicon-On-Insulator (SOI) substrate or SOI wafer known in the art.

In some examples, a method of forming the bit line 112 comprises: providing the first substrate structure 13 as shown in FIG. 8, wherein the first substrate structure 13 comprises the first dielectric layer 161 and the semiconductor layer 1111 that are stacked together; forming a first trench 171 extending through the semiconductor layer 1111 and the first dielectric layer 161 along the first direction, wherein the first trench 171 extends along the second direction, and the first trench 171 divides the semiconductor layer 1111 into semiconductor strips 1112; and reducing the size of the first dielectric layer 161 in the third direction, and forming the bit line 112 extending along the second direction on a side of the semiconductor strip 1112 close to first dielectric layer 161.

In some examples, the method of forming the bit line 112 further comprises: removing part of the first dielectric layer 161 to reduce the size of the first dielectric layer 161 in the third direction, to form a first opening 172 with an opening direction facing the third direction, wherein the first opening 172 extends along the second direction; filling the first opening 172 to form the second dielectric layer 162, wherein the second dielectric layer 162 covers a sidewall of the first trench 171, and the second dielectric layer 162 and the first dielectric layer 161 surround a side of the semiconductor strip 1112 and surround a side surface of the semiconductor strip 1112 close to the first dielectric layer 161, to expose a side of the semiconductor strip 1112 away from the first dielectric layer 161; filling a remaining cavity of the first trench 171 to form the third dielectric layer 163; removing the second dielectric layer 162 on a side of the first dielectric layer 161 to form a second trench 173, wherein the second trench 173 exposes the first dielectric layer 161, a side of the semiconductor strip 1112, and the side of the semiconductor strip 1112 close to the first dielectric layer 161; and forming the bit line 112 in a portion of the second trench 173 that extends toward the first dielectric layer 161.

With reference to FIG. 9, the semiconductor layer 1111 and the first dielectric layer 161 are etched to form the first trench 171 extending through the semiconductor layer 1111 and the first dielectric layer 161. The first trench 171 exposes the stop layer 151, which serves as a barrier layer for the etching, and may not be etched or may be partially etched. The bottom of the first trench 171 may stop at an upper surface of the stop layer 151, and the bottom of the first trench 171 may extend into the stop layer 151 but does not extend through the stop layer 151. An etching process may include dry etching, wet etching, or a combination thereof. In an example, the semiconductor layer 1111 may include silicon, the first dielectric layer 161 may include silicon oxide, the stop layer 151 may include silicon oxide that is denser than silicon oxide of the first dielectric layer 161, or the stop layer 151 may include silicon nitride, so that the stop layer 151 has a better etching stop or barrier effect during etching of the semiconductor layer 1111 and the first dielectric layer 161.

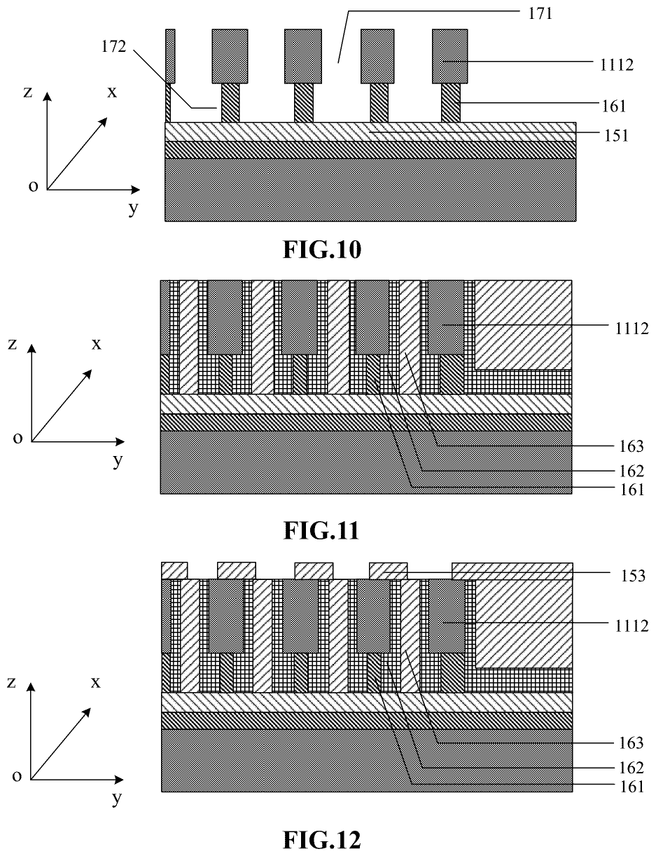

With reference to FIG. 10, the first dielectric layer 161 exposed from the sidewall of the first trench 171 is etched to remove part of the first dielectric layer 161, thereby reducing the size of the first dielectric layer 161 in the y direction and forming the first opening 172 facing the positive y direction and negative y direction. Part of the thickness (or part of the length) of the first dielectric layer 161 in the y direction is retained, to prevent the semiconductor strip 1112 from collapsing due to loss of support. The etching process for removing the first dielectric layer 161 in FIG. 10 may include gas etching or wet etching, and the amount of etching may be controlled by controlling an etching duration, so as to form the first opening 172 without causing the collapse of the semiconductor strip 1112.

With reference to FIG. 11, the second dielectric layer 162 covering the sidewalls on both sides of the first trench 171 is formed in the first opening 172. The second dielectric layer 162 extends into the first opening 172 to fill the first opening 172. The second dielectric layer 162 may have L-shaped morphology, with a portion extending along the z direction and covering a side of the semiconductor strip 1112 in the y direction, and the other portion extending along the y direction and being located at the bottom of the semiconductor strip 1112. The second dielectric layer 162 may be in contact with the first dielectric layer 161. Two L-shaped second dielectric layers 162 and the first dielectric layer 161 enclose the bottom of the semiconductor strip 1112 and two sides of the semiconductor strip 1112 in the y direction, exposing a top surface of the semiconductor strip 1112 away from the first dielectric layer 161. After the second dielectric layer 162 is formed, the third dielectric layer 163 extending along the z direction is formed in the remaining cavity of the first trench 171, and the third dielectric layer 163 may fully fill the remaining space of the first trench 171.

In an example, the second dielectric layer 162 and the third dielectric layer 163 may be formed by deposition, and the deposition process includes, but is not limited to, Chemical Vapor Deposition (CVD), Physical Vapor Deposition (PVD), and Atomic Layer Deposition (ALD).

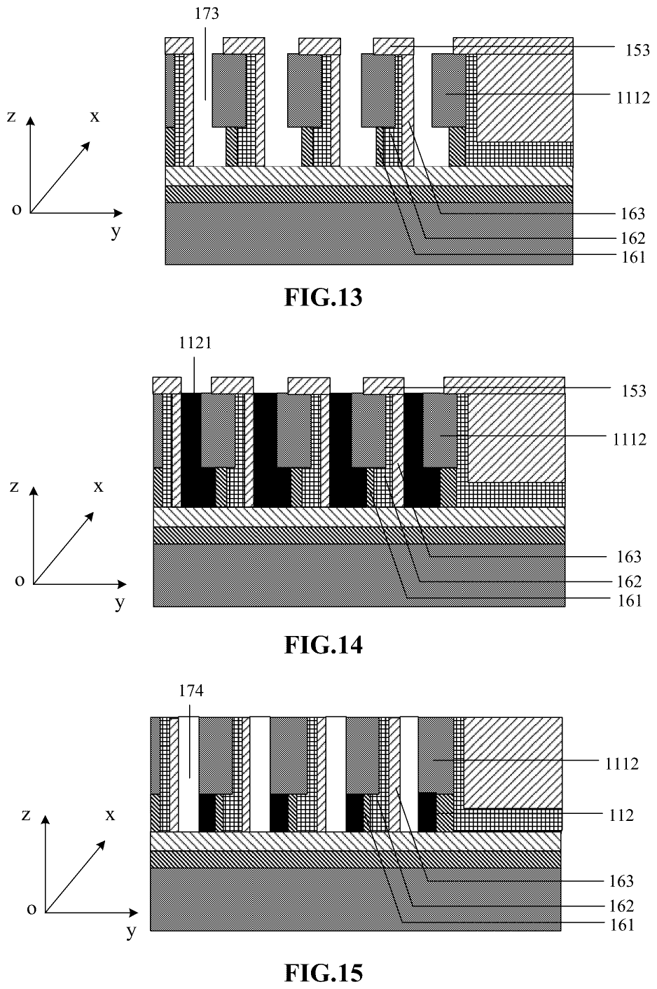

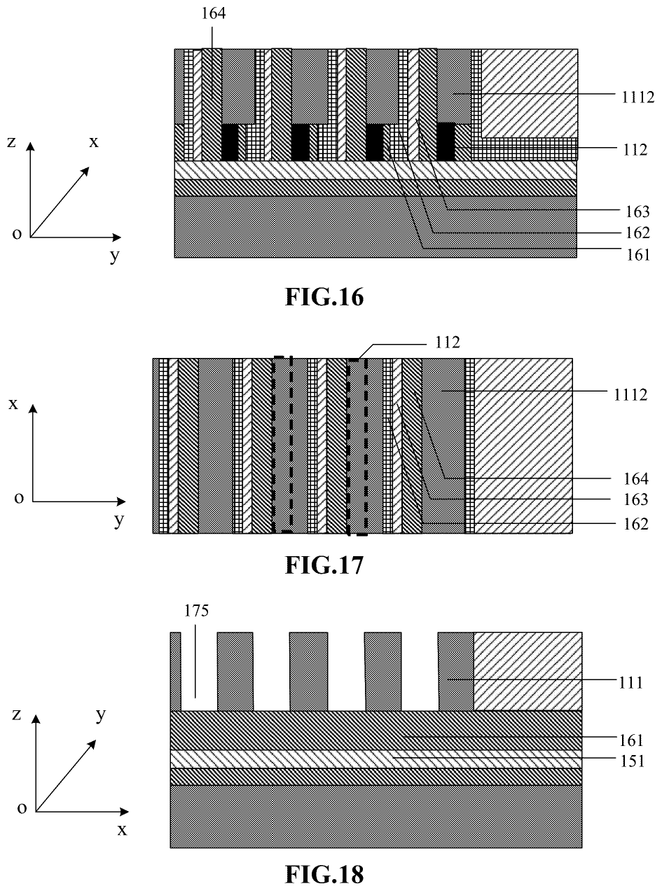

With reference to FIG. 12, a patterned mask layer 153 is formed. With reference to FIG. 13, the mask layer 153 serves as an etching mask, to remove the second dielectric layer 162 on one side of the first dielectric layer 161 by etching and retain the second dielectric layer 162 on the other side to form the second trench 173. For example, the second dielectric layer 162 on a left side of the first dielectric layer 161 is removed, and the second dielectric layer 162 and the third dielectric layer 163 on a right side of the first dielectric layer 161 are retained. The second trench 173 may have L-shaped morphology. The second trench 173 exposes a left side of the semiconductor strip 1112 in the y direction, and the bottom of the second trench 173 also exposes a bottom surface of the semiconductor strip 1112. The bottom of the semiconductor strip 1112 exposed by the bottom of the second trench 173 is only a bottom surface of the first dielectric layer 161 on the left side, and the bottom of the second trench 173 exposes a left side surface of the first dielectric layer 161 in the y direction. A bit line 112 (such as the bit line 112 shown in FIG. 16) is formed in a portion at the bottom of the second trench 173 that extends toward the first dielectric layer 161, with a left side of the bit line 112 being aligned with a left side of the semiconductor strip 1112 in the z direction and a right side of the bit line 112 being in contact with the first dielectric layer 161. In some other examples, by adjusting the position of the pattern of mask layer 153, the second dielectric layer 162 on the right side of the first dielectric layer 161 may be removed by etching, and the second dielectric layer 162 and the third dielectric layer 163 on the left side of the first dielectric layer 161 may be retained, so that the right side of the formed bit line 112 is aligned with the right side of the semiconductor strip 1112 in the z direction.

In some examples, the method of forming the second trench 173 further comprises: removing part of a thickness of the third dielectric layer 163, to reduce the size of the third dielectric layer 163 in the third direction. With reference to FIG. 13, during removal of the second dielectric layer 162, part of the third dielectric layer 163 may be also removed. By reducing the size of the third dielectric layer 163 in the y direction, the size of the second trench 173 in the y direction is increased, thereby providing a larger space for depositing a conductive material in the second trench 173 subsequently to form the bit line 112, and improving a fabrication yield of the bit line 112.

In some examples, composition materials of the first dielectric layer 161, the second dielectric layer 162, and the third dielectric layer 163 may be selected according to the selectivity of etchant for different materials, and suitable etchants are selected for different film layers. For example, the semiconductor strip 1112 may include silicon, the first dielectric layer 161 may include silicon oxide, the second dielectric layer 162 may include aluminum oxide, and the third dielectric layer 163 may include silicon nitride. The removal of the second dielectric layer 162 by etching may be performed using an etchant including acidic liquid or gas, such as hydrochloric acid or sulfuric acid, etc., and the second dielectric layer 162 is removed using isotropic and anisotropic diffusion of the etchant, to form the L-shaped second trench 173 as shown in FIG. 13. The semiconductor strip 1112 and the third dielectric layer 163 may be substantially not etched during etching of the second dielectric layer 162. For another example, the semiconductor strip 1112 may include silicon, the first dielectric layer 161 may include silicon oxide, the second dielectric layer 162 may include silicon nitride, and the third dielectric layer 163 may include aluminum oxide. The removal of the second dielectric layer 162 by etching may be performed using an etchant including phosphoric acid, wherein the second dielectric layer 162 is removed using isotropic and anisotropic diffusion of the etchant, to form the L-shaped second trench 173 as shown in FIG. 13.

In some examples, the method of forming the bit line 112 further comprises:

With reference to FIG. 14, the second trench 173 is filled to form a first conductive layer 1121. The first conductive layer 1121 comprises a portion extending along the first direction and a portion extending along the third direction respectively, and the portion of the first conductive layer 1121 extending along the third direction extends toward the first dielectric layer 161. With reference to FIG. 15, the portion of the first conductive layer 1121 extending along the first direction is removed to form a third trench 174, wherein the third trench 174 exposes the third dielectric layer 163 and one side of the semiconductor strip 1112, and a remaining portion of the first conductive layer 1121 forms the bit line 112.

In some examples, with reference to FIG. 15, the portion of the first conductive layer 1121 extending along the z direction is removed by etching, and a remaining portion of the first conductive layer 1121 serves as the bit line 112. The left side of the bit line 112 along the y direction and the left side of the semiconductor pillar 111 along the y direction are aligned with each other in the z direction, and the size of the bit line 112 in the y direction is less than the size of the semiconductor pillar 1112 in the y direction. During the etching process, parameters, such as an etching duration, etc., may be controlled so that the left side of the bit line 112 is completely aligned with the left side of the semiconductor pillar 111 in the z direction. Alternatively, in some examples, since the side of the semiconductor strip 1112 is partially over-etched, the left side of the bit line 112 protrudes from the left side of the semiconductor strip 1112 along the negative y direction. Alternatively, in some examples, since the bit line 112 is over-etched, the left side of the semiconductor strip 1112 protrudes from the left side of the semiconductor strip 1112 along the negative y direction. A distance of the above-mentioned protrusion is within the range of process control of the examples of the present disclosure, for example, a distance by which the left side of the bit line 112 protrudes from the semiconductor strip 1112 may be less than 5% of the size of the bit line 112 in the y direction.

In some examples, with reference to FIG. 16, the fabrication method of the first semiconductor structure 101 further comprises: filling the third trench 174 to form the fourth dielectric layer 164. FIG. 17 illustrates a top view of the device structure in FIG. 16, a dashed line box illustrates the bit line 112 extending under the semiconductor strip 1112, and the bit line 112 and the first dielectric layer 161 are hidden from view by the semiconductor strip 1112 and thus are not shown.

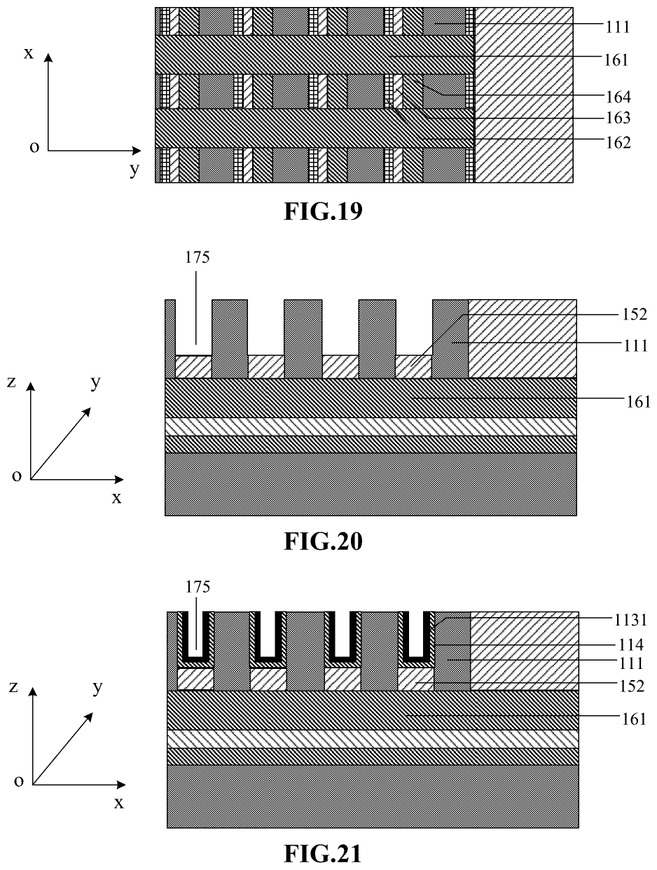

In some examples, a method of forming the semiconductor pillar 111 further comprises: with reference to FIG. 18, forming a fourth trench 175 extending through the semiconductor strip 1112. The fourth trench 175 divides the semiconductor strip 1112 into semiconductor pillars 111; and the fourth trench 175 extends along the third direction. The fabrication method of the first semiconductor structure 101 further comprises: forming the gate dielectric layer 114 and a word line 113 sequentially on at least one side of the semiconductor pillar 111. The bottom of the fourth trench 175 in FIG. 18 exposes the first dielectric layer 161. The bottom of the fourth trench 175 may stop at the surface of the first dielectric layer 161, or may extend into but not extend through the first dielectric layer 161. FIG. 19 illustrates a top view of the device structure in FIG. 18, and only the first dielectric layer 161 exposed by two fourth trenches 175 extending along the y direction is shown in FIG. 19. The first dielectric layer 161 in FIG. 19 may illustrate the position of the fourth trench 175. The fabrication of the fourth trench 175 may be performed after or before the formation of the bit line 112, and there is no limitation on the sequence of fabrication. The fabrication of the gate dielectric layer 114 and the word line 113 may be performed after the formation of the fourth trench 175.

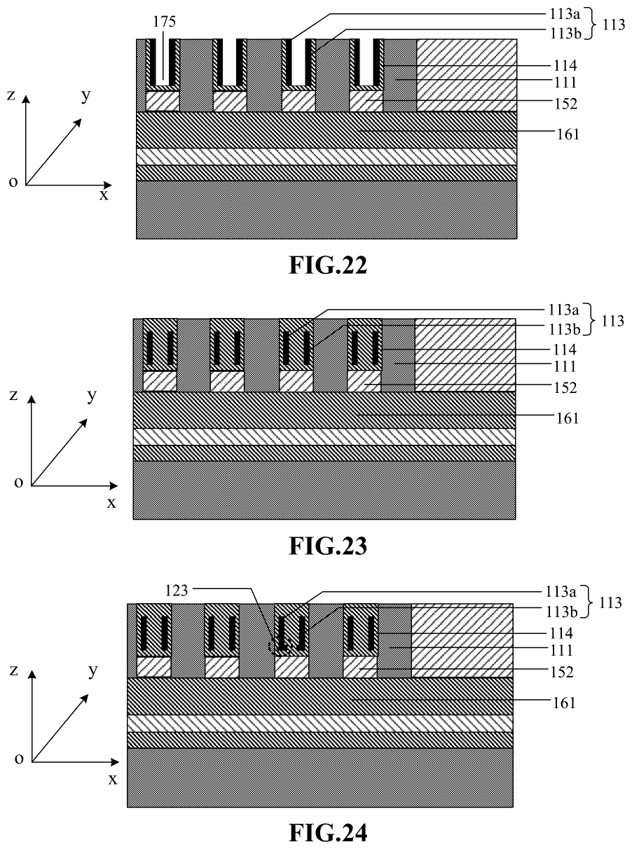

In some examples, the method of forming the word lines 113 comprises: with reference to FIG. 20, forming a sixth dielectric layer 152 at the bottom of the fourth trench 175, wherein a size of the sixth dielectric layer 152 in the first direction is less than the size of the semiconductor pillar 111 in the first direction; with reference to FIG. 21, forming the gate dielectric layer 114 and a second conductive layer 1131 sequentially on a sidewall of the fourth trench 175 and on the sixth dielectric layer 152; and with reference to FIG. 22, extending through the second conductive layer 1131 along the first direction, to form the first word line 113a and the second word line 113b on two sides of the semiconductor pillar 111 that are opposite along the second direction.

In FIG. 20, the formation of the sixth dielectric layer 152 may increase a distance between the word line 113 and the first dielectric layer 161, so that the word line 113 is in the middle of the semiconductor pillar 111. In some other examples, the sixth dielectric layer 152 may not be formed, and the word line 113 may be formed directly based on the fourth trench 175 in FIG. 18.

In FIG. 21, the gate dielectric layer 114 formed by deposition covers a sidewall and a bottom surface of the fourth trench 175, the second conductive layer 1131 formed by deposition covers the gate dielectric layer 114, and the second conductive layer 1131 has U-shaped morphology. In FIG. 22, the second conductive layer 1131 is etched along the z direction, the second conductive layer 1131 on the bottom surface of the fourth trench 175 is etched through to break the bottom of the U-shaped second conductive layer 1131 into two word lines 113, and one semiconductor pillar 111 corresponds to two word lines 113. During etching through of the second conductive layer 1131, the gate dielectric layer 114 may be etched through along the z direction or the gate dielectric layer 114 may be not etched.

With reference to FIG. 23, the remaining space of the fourth trench 175 is filled with a dielectric material, to electrically isolate adjacent ones of the word lines 113. Composition materials of the gate dielectric layer 114 and the dielectric material may be the same and may be both silicon oxide, and there may be no obvious physical boundary between the gate dielectric layer 114 and the dielectric material.

In some examples, with reference to FIG. 24, during extending through the second conductive layer 1131, a portion of the second conductive layer 1131 that remains on the sixth dielectric layer 152 forms the protrusion 123 at an end of at least one of the first word line 113a or the second word line 113b close to the bit line 112, and the protrusion 123 extends in a direction away from the semiconductor pillar 111. The device structure shown in FIG. 24 is an illustration of a structure after the formation of the word lines 113 is completed and the fourth trench 175 is filled with the dielectric material. During extending through the second conductive layer 1131 along the z direction, due to a load effect of etching, there may be some residual portions of the bottom of the second conductive layer 1131 that are not completely removed, which form the protrusion 123 at the end of at least one of the first word line 113a or the second word line 113b close to the bit line 112, such as the protrusion 123 on the first word line 113a extending along the positive x direction, and/or the protrusion 123 on the second word line 113b extending along the negative x direction.

In some examples, the word line 113 covers one side of the semiconductor pillar 111 along a direction perpendicular to the first direction; or the word line 113 covers two sides of the semiconductor pillar 111 along a direction perpendicular to the first direction; or the word line 113 covers three sides of the semiconductor pillar 111 along a direction perpendicular to the first direction.

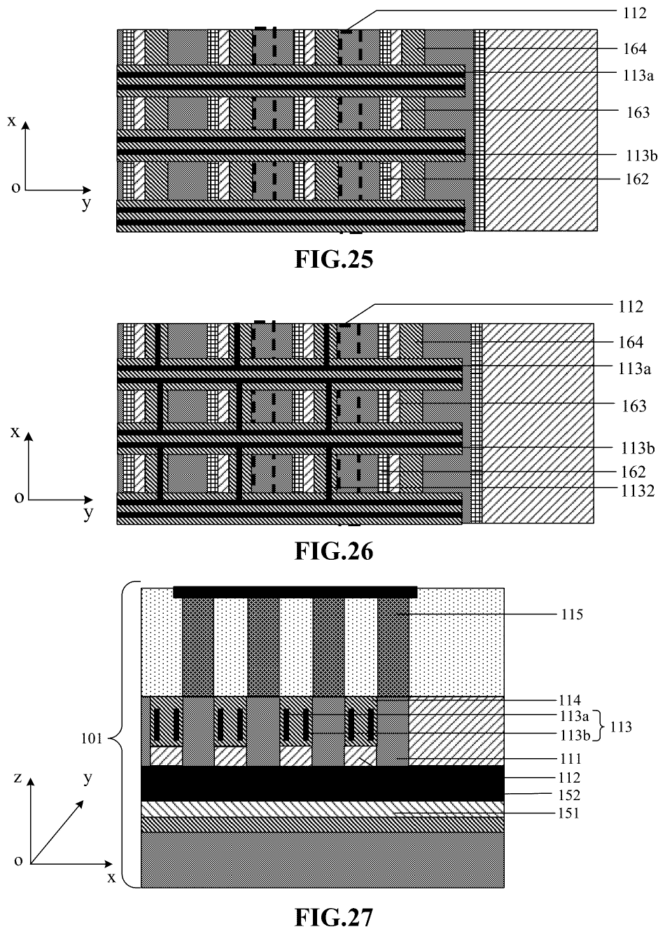

FIG. 25 illustrates a top view of the device structure in FIG. 23. One side of the semiconductor pillar 111 in the y direction is covered by the second dielectric layer 162, and the word line 113 may cover any one of the other three sides of the semiconductor pillar 111 that are not covered by the dielectric layer. In FIG. 25, one semiconductor pillar 111 corresponds to two word lines 113, i.e., the first word line 113a and the second word line 113b, which cover two sides of the semiconductor pillar 111 along the x direction. Alternatively, the semiconductor pillar 111 may correspond to either one of the first word line 113a and the second word line 113b. The word line extends along the y direction and covers, along the x direction, one side of the semiconductor pillar 111 in the x direction. Alternatively, in some examples, with reference to FIG. 26, a bridging structure 1132 is disposed between the first word line 113a and the second word line 113b corresponding to one semiconductor pillar 111. The bridging structure 1132 extends along the x direction and covers one of opposite sides of the second dielectric layer 162 along the y direction. The bridging structure 1132 may be part of the word line 113.

In some examples, the fabrication method of the first semiconductor structure 101 further comprises: forming a capacitor structure 115 on a side of the semiconductor pillar 111 away from the bit line 112, wherein the capacitor structure 115 is coupled with the second end of the semiconductor pillar 111.

In some examples, a size of an end of the capacitor structure 115 away from the bit line 112 in at least one of the second direction or the third direction is greater than a size of an end of the capacitor structure 115 close to the bit line 112 in at least one of the second direction or the third direction.

In some examples, the capacitor structure 115 comprises: a first electrode 1151, and a fifth dielectric layer 1152 and a second electrode 1153 that surround the first electrode 1151, wherein the fifth dielectric layer 1152 is located between the first electrode 1151 and the second electrode 1153.

With reference to FIG. 27, a dielectric material layer may be formed on the semiconductor pillar 111, and the dielectric material layer may be etched to form an opening exposing the end of the semiconductor pillar 111 away from the bit line 112, and the first electrode 1151, and the fifth dielectric layer 1152 and the second electrode 1153 that surround the first electrode 1151 are formed sequentially in the opening. The fifth dielectric layer 1152 is located between the first electrode 1151 and the second electrode 1153. Due to the load effect of etching, the top size of the opening for forming the capacitor structure 115 is larger than its bottom size, and a size of an end of the capacitor structure 115 away from the bit line 112 in the x direction is greater than a size of an end of the capacitor structure 115 close to the bit line 112 in the x direction. The specific structure of the capacitor structure 115 may be referred to FIGS. 4 and 5.

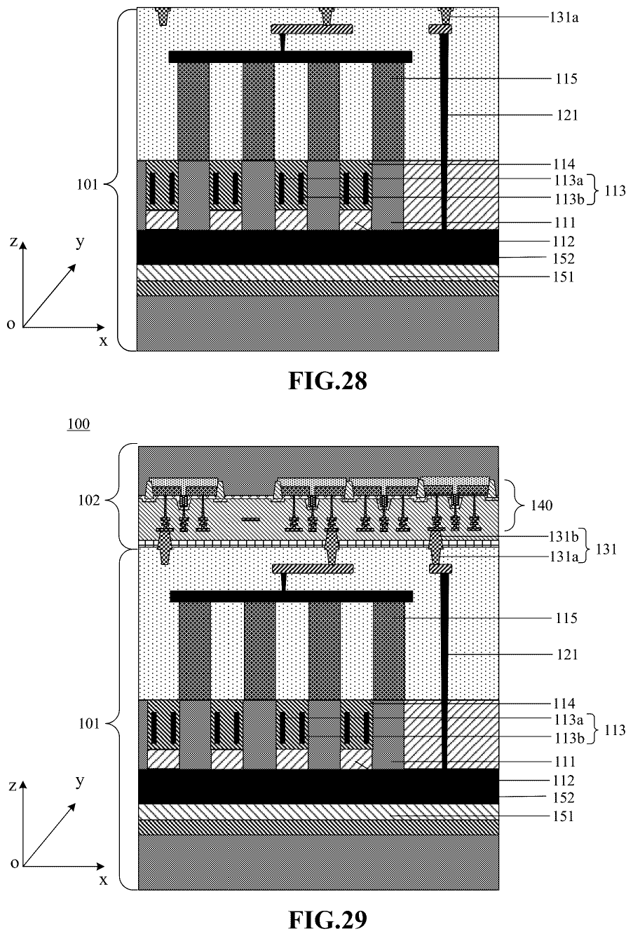

With reference to FIG. 28, the first contact structure 121 coupled with the bit line 112 is formed, the bonding contact 131a is formed on a side of the first semiconductor structure 101 away from the bit line 112, and the first contact structure 121 is coupled with at least one bonding contact 131a. The second contact structure 122 coupled with the word line 113 is formed, and the second contact structure 122 is coupled with at least one bonding contact 131b. The second contact structure 122 is not shown in FIG. 28 due to the angle of the cross-sectional view, and may be referred to FIG. 2.

Devices such as the bit line 112, the word line 113, the semiconductor pillar 111, and capacitor structure 115, etc. of the examples of the present disclosure may be all formed on one side surface (front side) of the first substrate 13. As such, it is not necessary to bond a carrier wafer to the front side of the wafer and form the bit line by performing a back side process on the wafer after flipping the carrier wafer, thereby avoiding deformation of the devices caused by pressing of the carrier wafer, for example, avoiding deformation of the bonding contact 131a, the first contact structure 121, and the second contact structure 122, which improves the bonding alignment accuracy and fabrication yield.

In some examples, the fabrication method of the memory device 100 comprises: with reference to FIG. 29, providing the second semiconductor structure 102; and bonding the second semiconductor structure 102 and the first semiconductor structure 101 on a side of the capacitor structure 115 away from the bit line 112.

Prior to the bonding, the second semiconductor structure 102 further comprises the bonding contact 131b. The planes to be bonded of the first semiconductor structure 101 and the second semiconductor structure 102 are bonded, and an interface where the planes to be bonded of the two semiconductor structures contact each other is a bonding interface. The bonding contacts 131a and 131b of the first semiconductor structure 101 and the second semiconductor structure 102 contact each other at the bonding interface, to achieve electrical signal interconnection between the first semiconductor structure 101 and the second semiconductor structure 102. There may be no physical boundary between the bonding contact 131a and the bonding contact 131b after the bonding, and they may be considered as the bonding contact 131. The bonding contact 131 extends through the bonding interface. The bonding of the first semiconductor structure 101 and the second semiconductor structure 102 may be bonding a wafer comprising the first semiconductor structure 101 and a wafer comprising the second semiconductor structure 102.

In some other examples, the second semiconductor structure 102 and the first semiconductor structure 101 may be not connected by bonding. The second semiconductor structure 102 is formed based on the structure of the first semiconductor structure 101, the bonding contact 131 serves as a conductive contact or no bonding contact 131 is provided, and the first contact structure 121 and the second contact structure 122 are coupled with an interconnection structure in the peripheral circuit 140 to complete the electrical signal interconnection.

In some examples, with reference to FIGS. 1 and 2, the fabrication method further comprises: forming the first interconnection layer 141 and the pad 142 that are located on a side surface of the second semiconductor structure 102 away from the first semiconductor structure 101, wherein the first interconnection layer 141 and the pad 142 are coupled with the second semiconductor structure 102. The first interconnection layer 141 may be coupled with a device in the peripheral circuit 140, to provide power or communication for the device in the peripheral circuit 140. The pad 142 may serve as an IO interface of the memory device 100 for external power supply or external communication of the memory device 100. In the examples of the present disclosure, the lead structures such as the first interconnection layer 141 and the pad 142, etc. are formed after bonding. Compared with the lead structures formed prior to the bonding, it is not necessary to bond a front side of the second semiconductor structure 102 by using a carrier wafer and then flip it to form the lead structures such as the first interconnection layer 141 and the pad 142, etc., thereby avoiding deformation of the devices caused by pressing of the carrier wafer, for example, avoiding deformation of the bonding contact 131a, which improves the bonding alignment accuracy and fabrication yield. In some examples, the first interconnection layer 141 and the pad 142 may be formed prior to the bonding, and the second semiconductor structure 102 comprising the first interconnection layer 141 and the pad 142 is bonded with the first semiconductor structure 101.

According to the examples of the present disclosure, the bit line is formed in the first substrate structure. The bit line may be pre-buried under the semiconductor pillar before the semiconductor pillar is formed, and the semiconductor pillar, the word line, and the capacitor structure may be formed subsequently on the bit line. Compared with the solution in which the semiconductor pillar is formed first, the word line is formed along the front side of the wafer, and the bit line is formed along the back side of the wafer, both the bit line and the word line of the examples of the present disclosure may be formed on the front side of the wafer, so that the process sizes are easier to control, which is conducive to improving the fabrication yield. The examples of the present disclosure do not need to perform a back side process on a wafer with a capacitor structure and a wafer with a peripheral circuit, and do not need to use the carrier wafer to perform front side bonding on the wafer with related device structures followed by flipping it, thereby avoiding deformation of the device structures caused by pressing of the carrier wafer, which improves the fabrication yield.

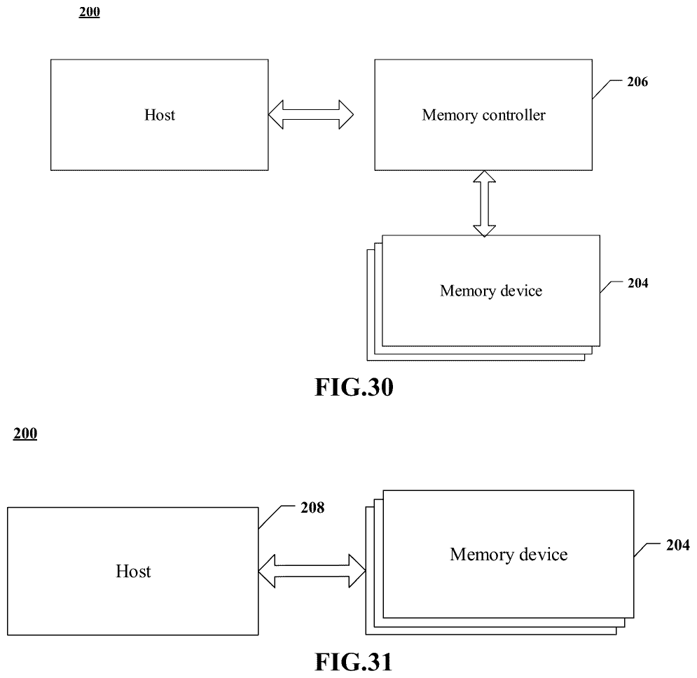

According to some aspects of examples of the present disclosure, FIG. 30 provides a memory system 202 comprising: a memory device 204 comprising the memory device 100; and a memory controller 206 that is coupled with the memory device 204 and controls the memory device 204. The memory device 100 of the examples of the present disclosure may serve as the memory device 204, or at least may be some devices in the memory device.

With reference to FIG. 30, examples of the present disclosure provide a system 200 comprising a host 208. The system 200 may be a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 30, the system 200 may comprise the host 208 and the memory system 202, wherein the memory system 202 has one or more memory devices 204 and the memory controller 206. The host 208 may be a processor (e.g., a central processing unit (CPU)) or a system on chip (SOC) (e.g., an application processor (AP)) of an electronic apparatus. The host 208 may be configured to send or receive data to or from the memory device 204.

According to some implementations, the memory controller 206 is coupled to the memory device 204 and the host 208 and is configured to control the memory device 204 to perform read, write or refresh operations. The memory controller 206 can manage data stored in the memory device 204 and communicate with the host 208. The memory device 204 comprises a DRAM, or a package structure formed by stacking a plurality of DRAMs, such as an HBM or HMC packaging structure. The memory system 202 may serve as a memory of the host 208 in the system 200 or a buffer of the system 200. In some examples, the memory system 202 may be used as an auxiliary device in a solid-state drive, which can bring improvements on reading and writing, etc. of the solid-state drive. At present, most high-end solid-state drive products select embedded DRAMs to improve the performance of products, and improve the random read-write speeds. In an example, when writing a file, especially a small file, the small file is stored in a flash after being processed by the DRAMs, such that the solid-state drive has higher storage efficiency and faster speed. The flash comprises a non-volatile memory, including, but not limited to, a 2D NAND memory or a 3D NAND memory.

In some other examples, with reference to FIG. 31, the system 200 may only comprise the host 208 and the memory device 204 coupled with the host. A controller that controls the memory device 204 may be inside the host 208, for example, may be a memory controller integrated in a central processing unit (CPU), or a south bridge or north bridge chip integrated in a mainboard of the system 200. The memory device 204 may include, but is not limited to, a double-data-rate synchronous dynamic random access memory with the DDR4 memory specification or DDR5 memory specification, and a low-power double-data-rate synchronous dynamic random access memory with the LPDDR5 memory specification.

In some examples provided by the present disclosure, it is to be understood that the disclosed apparatus and method may be implemented by other manners. The examples of apparatuses described above are illustrative only, for example, the division of units is merely a logical functional division. In a real implementation, there may be other manners for division. For instance, a plurality of units or assemblies may be combined, or may be integrated to another system, or some features may be omitted or not performed. In addition, the various components as shown or as discussed may be coupled directly or indirectly. The methods disclosed in several method examples provided by the present disclosure may be combined randomly in case of no conflicts, so as to obtain a new method example.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory device, comprising a first semiconductor structure, wherein the first semiconductor structure comprises:
a semiconductor pillar extending along a first direction, wherein the semiconductor pillar has a first end and a second end that are opposite in the first direction; and
a bit line that is located on a side of the semiconductor pillar close to the first end and is coupled with the first end, wherein the bit line extends along a second direction perpendicular to the first direction; a first side of the bit line along a third direction and a first side of the semiconductor pillar along the third direction are aligned with each other in the first direction; and a size of the bit line in the third direction is less than a size of the semiconductor pillar in the third direction, wherein the third direction is perpendicular to the first direction and intersects the second direction.

2. The memory device of claim 1, wherein a second side of the bit line along the third direction is located between the first side and a second side of the semiconductor pillar along the third direction.

3. The memory device of claim 1, wherein a projection of the bit line on a first plane is offset from a projection of the semiconductor pillar on the first plane along the third direction, and wherein the first plane is perpendicular to the first direction.

4. The memory device of claim 3, further comprising:
a dielectric layer located between two adjacent ones of the bit lines in the third direction.

5. The memory device of claim 4, wherein the dielectric layer comprises: a first dielectric layer, a second dielectric layer, a third dielectric layer, and a fourth dielectric layer disposed sequentially along the third direction, and wherein
the first dielectric layer is located at an end of the semiconductor pillar close to the first end, a sum of a size of the first dielectric layer and the size of the bit line in the third direction is less than the size of the semiconductor pillar in the third direction, a projection of the first dielectric layer on a second plane overlaps a projection of the bit line on the second plane, and the second plane is perpendicular to the third direction;
the second dielectric layer comprises a first portion extending along the first direction and a second portion extending along the third direction, the second portion is located between the first dielectric layer and the first portion, and a projection of the second portion on the second plane overlaps the projection of the bit line on the second plane; and
the third dielectric layer and the fourth dielectric layer both extend along the first direction.

6. The memory device of claim 5, wherein
a composition material of the first dielectric layer and a composition material of the fourth dielectric layer comprise silicon oxide; and
a composition material of the second dielectric layer and a composition material of the third dielectric layer both comprise aluminum oxide or silicon nitride.

7. The memory device of claim 1, further comprising:
a word line located on at least one side of the semiconductor pillar, wherein at least part of the word line extends along the third direction; and
a gate dielectric layer located between the word line and the semiconductor pillar.

8. The memory device of claim 7, wherein the word line comprises a first word line and a second word line that are respectively located on two sides of the semiconductor pillar that are opposite along the second direction.

9. The memory device of claim 8, wherein at least one of the first word line or the second word line comprises a protrusion located at an end of at least one of the first word line or the second word line close to the bit line; and the protrusion extends in a direction away from the semiconductor pillar.

10. The memory device of claim 7, wherein the word line covers one side of the semiconductor pillar along a direction perpendicular to the first direction; or
the word line covers two sides of the semiconductor pillar along a direction perpendicular to the first direction; or
the word line covers three sides of the semiconductor pillar along a direction perpendicular to the first direction.

11. The memory device of claim 1, wherein
the memory device further comprises a capacitor structure located on a side of the semiconductor pillar away from the bit line, and the capacitor structure is coupled with the second end.

12. The memory device of claim 11, wherein a size of an end of the capacitor structure away from the bit line in at least one of the second direction or the third direction is greater than a size of an end of the capacitor structure close to the bit line in at least one of the second direction or the third direction.

13. The memory device of claim 11, wherein the capacitor structure comprises:
a first electrode, and a fifth dielectric layer and a second electrode that surround the first electrode, wherein the fifth dielectric layer is located between the first electrode and the second electrode.

14. The memory device of claim 11, further comprising:
a second semiconductor structure, wherein the second semiconductor structure comprises a peripheral circuit located on a side of the capacitor structure away from the semiconductor pillar, and the second semiconductor structure is bonded with the first semiconductor structure.

15. The memory device of claim 14, wherein the second semiconductor structure further comprises:
a first interconnection layer and a pad that are located on a side surface of the second semiconductor structure away from the first semiconductor structure, wherein the first interconnection layer and the pad are coupled with the second semiconductor structure.

16. A memory device, comprising:
a semiconductor pillar extending along a first direction, wherein the semiconductor pillar has a first end and a second end that are opposite in the first direction; and
a bit line that is located on a side of the semiconductor pillar close to the first end and is coupled with the first end, wherein the bit line extends along a second direction perpendicular to the first direction; a first side of the bit line along a third direction and a first side of the semiconductor pillar along the third direction are aligned with each other in the first direction; and a size of the bit line in the third direction is less than a size of the semiconductor pillar in the third direction, wherein the third direction is perpendicular to the first direction and intersects the second direction;
a capacitor structure that is located on a side of the semiconductor pillar away from the bit line and is coupled with the second end; and
a peripheral circuit located on a side of the capacitor structure away from the semiconductor pillar, wherein the peripheral circuit is at least coupled with the capacitor structure and the bit line.

17. A fabrication method of a memory device, comprising:
forming a first semiconductor structure, wherein the forming of the first semiconductor structure comprises:
forming a semiconductor pillar extending along a first direction, wherein the semiconductor pillar has a first end and a second end that are opposite in the first direction; and
forming a bit line extending along a second direction perpendicular to the first direction on a side of the semiconductor pillar close to the first end, wherein the bit line is coupled with the first end; a first side of the bit line along a third direction and a first side of the semiconductor pillar along the third direction are aligned with each other in the first direction; and a size of the bit line in the third direction is less than a size of the semiconductor pillar in the third direction, wherein the third direction is perpendicular to the first direction and intersects the second direction.

18. The fabrication method of claim 17, wherein forming the bit line comprises:
providing a first substrate structure, wherein the first substrate structure comprises a first dielectric layer and a semiconductor layer that are stacked together;
forming a first trench extending through the semiconductor layer and the first dielectric layer along the first direction, wherein the first trench extends along the second direction, and the first trench divides the semiconductor layer into semiconductor strips; and
reducing a size of the first dielectric layer in the third direction, and forming the bit line extending along the second direction on a side of the semiconductor strip close to the first dielectric layer.

19. The fabrication method of claim 18, wherein the forming of the first semiconductor structure comprises:
providing a first substrate comprising a first insulation layer, and providing a second substrate comprising a second insulation layer; and
bonding the first insulation layer and the second insulation layer to form the first dielectric layer, and thinning a side surface of the first substrate away from the first dielectric layer to form the semiconductor layer.

20. The fabrication method of claim 18, wherein the forming the bit line further comprises:
removing part of the first dielectric layer to reduce the size of the first dielectric layer in the third direction, to form a first opening with an opening direction facing the third direction, wherein the first opening extends along the second direction;
filling the first opening to form a second dielectric layer, wherein the second dielectric layer covers a sidewall of the first trench; and the second dielectric layer and the first dielectric layer surround a side of the semiconductor strip and surround a side surface of the semiconductor strip close to the first dielectric layer, to expose a side surface of the semiconductor strip away from the first dielectric layer;
filling a remaining cavity of the first trench to form a third dielectric layer;
removing the second dielectric layer on a side of the first dielectric layer to form a second trench, wherein the second trench exposes the first dielectric layer, the side of the semiconductor strip, and the side surface of the semiconductor strip close to the first dielectric layer; and
forming the bit line in a portion of the second trench that extends toward the first dielectric layer.
